(19) United States
(12) Patent Application Publication
(10) Pub. No.: US 2026/0182311 A1
(43) Pub. Date: Jun. 25, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Shu-Hui SU, Tucheng City (TW); Hsin-Li CHENG, Hsinchu (TW); YingKit Felix TSUI, Cupertino, CA (US)

(21) Appl. No.: 18/999,083

(22) Filed: Dec. 23, 2024

(51) Int. Cl. H10P 74/00; H10P 74/20; H10W 20/40; H10W 90/00

(52) U.S. Cl. CPC H10P 74/273; H10P 74/203; H10W 20/496; H10W 90/792

(57) ABSTRACT

Sacrificial test pads are formed in a semiconductor die, used for testing operations, and then removed after the testing operations have been completed. The removal of the sacrificial test pads eliminates any adverse effects (e.g., on structures and/or bonding of the semiconductor die) that may have been caused by damage to the sacrificial test pads from multiple test probe applications. For example, the removal of the sacrificial test pads prior to forming portions of an interconnect layer and forming a bonding region prevents any uneven surfaces, increased oxidation, and/or etching contamination that could have been caused by marks, recesses, protrusions, and/or other imperfections in the sacrificial test pads. As a result, metallization structures, interconnect structures, and bonding structures may be subsequently formed without defects that may have been attributed to damaged test pads. Testing interconnect structures used in connection with the testing operations may remain in the semiconductor die.

### BACKGROUND

Various semiconductor device packing techniques may be used to incorporate one or more semiconductor dies into a semiconductor device package. In some cases, semiconductor dies may be stacked in a semiconductor device package to achieve a smaller horizontal or lateral footprint of the semiconductor device package and/or to increase the density of the semiconductor device package. Semiconductor device packing techniques that may be performed to integrate a plurality of semiconductor dies in a semiconductor device package may include integrated fanout (InFO), package on package (PoP), chip on wafer (CoW), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a semiconductor device described herein.

FIG. 2 is a diagram of an example implementation of a capacitor structure described herein.

FIGS. 3A-3O are diagrams of an example implementation of forming a semiconductor device described herein.

FIG. 4 is a diagram of an example implementation of a semiconductor package described herein.

FIG. 5 is a diagram of an example implementation of a semiconductor device described herein.

FIG. 6 is a flowchart of an example process associated with forming a semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a wafer on wafer (WoW) semiconductor die package, semiconductor dies are directly bonded such that the semiconductor dies are vertically arranged in the WoW semiconductor die package. The use of direct bonding and vertical stacking of dies may reduce interconnect lengths between the semiconductor dies (which reduces power loss and signal propagation times) and may enable increased density of semiconductor die packages in a semiconductor device package that includes the WoW semiconductor die package.

Conductive test pads (e.g., metal test pads) may be formed on a semiconductor die to enable testing operations to be performed for the semiconductor die. Testing operations may be performed to test and/or verify proper operation of various aspects of the semiconductor die, and may include circuit probe (CP) testing, wafer acceptance testing (WAT), and/or electrical voltage stress (EVS) testing, among other examples. The testing operations may confirm whether circuits are operational, and/or add high voltages to the circuits to discover weak chips prior to performing wafer bonding. As a result of testing, wafers with circuits exhibiting issues may be omitted from further processing.

Test probes may be applied to the conductive test pads to perform CP testing, WAT, and/or EVS testing of integrated circuit devices (e.g., deep trench capacitor (DTC) devices and/or logic devices). In some cases, the application of the test probes to the conductive test pads may form marks, recesses, protrusions, and/or other imperfections in the conductive test pads, which may adversely affect wafer bonding. For example, damage to the conductive test pads from multiple test probe applications may cause the conductive test pads to have uneven surfaces. As a result, subsequently-formed bonding regions may have uneven topographies, which can cause weaker bonds in comparison to when bonding regions with even (e.g., planar) topographies are used. Conductive test pad damage may also increase surface areas of the conductive test pads, which can facilitate oxidation of metal material of the conductive test pads. The oxidized conductive test pads may impede circuit connections, leading to degraded device performance. In addition, protruding metal portions from damaged test pads may contaminate etching tools used in connection with forming recesses for metallization and/or interconnect structures, which may lead to the formation of defective metallization and/or interconnect structures.

In some implementations described herein, sacrificial test pads are formed in a semiconductor die, used for testing operations, and then removed after the testing operations have been completed. The removal of the sacrificial test pads eliminates any adverse effects (e.g., on structures and/or bonding of the semiconductor die) that may have been caused by damage to the sacrificial test pads from multiple test probe applications. For example, the removal of the sacrificial test pads prior to forming portions of an interconnect layer and forming a bonding region of the semiconductor die prevents any uneven surfaces, increased oxidation, and/or etching contamination that could have been caused by marks, recesses, protrusions, and/or other imperfections in the sacrificial test pads. As a result, metallization structures, interconnect structures, and bonding structures may be subsequently formed without defects that may have been attributed to damaged test pads. Testing interconnect structures used in connection with the testing operations may remain in the semiconductor die, with one or more dielectric layers formed over the testing interconnect structures. In this way, increased performance and bonding stability may be achieved for the semiconductor die in comparison to devices in which test pads remain in a final structure.

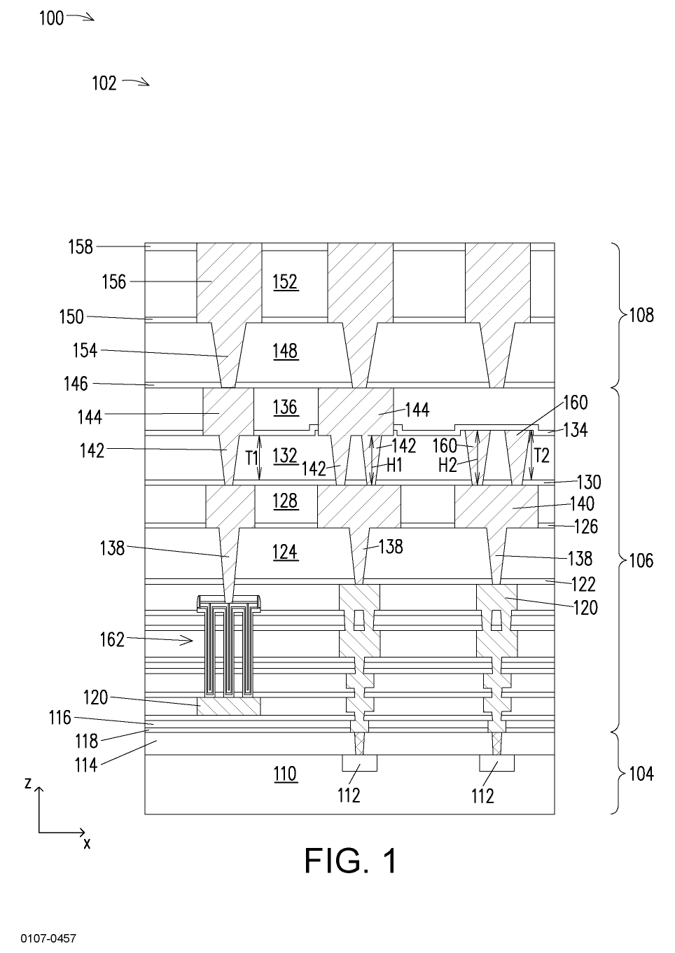

FIG. 1 is a diagram of an example implementation 100 of a semiconductor device 102 described herein. The semiconductor device 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor device 102 may include a memory die, an input/output (I/O) die, a pixel sensor die, and/or another type of semiconductor die. A memory die may include a static random access memory (SRAM) die, a DRAM die, a NAND die, a high bandwidth memory (HBM) die, and/or another type of memory die. In general, the semiconductor device 102 is a semiconductor device that includes one or more capacitor structures (e.g., deep trench capacitor (DTC) structures) in an interconnect layer and/or a device layer of the semiconductor device 102.

As shown in FIG. 1, the semiconductor device 102 includes a device layer 104, an interconnect layer 106 vertically arranged (e.g., in a z-direction) in the semiconductor device 102 with the device layer 104, and a bonding layer 108 vertically arranged (e.g., in a z-direction) in the semiconductor device 102 with the interconnect layer 106.

The device layer 104 may also be referred to as a device region of the semiconductor device 102. The device layer 104 includes a substrate layer 110. The substrate layer 110 may correspond to a portion of a semiconductor wafer on which the semiconductor device 102 is formed. The substrate layer 110 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 110 may extend in an x-direction and/or in a y-direction in the semiconductor device 102.

Integrated circuit devices 112 may be included in and/or on the substrate layer 110 in the device layer 104 of the semiconductor device 102. The integrated circuit devices 112 may include transistor structures (e.g., planar transistor structures, fin field effect transistor (finFET) structures, gate all around (GAA) transistor structures), pixel sensors, capacitors (e.g., DTC capacitors), resistors, inductors, photodetectors, transceivers, transmitters, receivers, optical circuits, logic devices, and/or other types of semiconductor devices that are formed in the device layer 104 (e.g., in and/or on the substrate layer 110) of the semiconductor device 102, as opposed to in the interconnect layer 106 of the semiconductor device 102.

A dielectric layer 114 is included over the substrate layer 110. The dielectric layer 114 includes an interlayer dielectric (ILD) layer, an etch stop layer (ESL), and/or another type of dielectric layer. The dielectric layer 114 includes dielectric material(s) that enable various portions of the substrate layer 110 and/or the integrated circuit devices 112 to be selectively etched or protected from etching, and/or to electrically isolate the integrated circuit devices 112 in the device layer 104. The dielectric layer 114 includes a silicon nitride (SiₓN_{y}), an oxide (e.g., a silicon oxide (SiOₓ) and/or another oxide material), and/or another type of dielectric material. The dielectric layer 114 may extend in the x-direction and/or in a y-direction in the semiconductor device 102.

The interconnect layer 106 of the semiconductor device 102 is included above the substrate layer 110 and above the integrated circuit devices 112 in the z-direction in the semiconductor device 102. The integrated circuit devices 112 may be electrically coupled to the interconnect layer 106. The interconnect layer 106 includes a plurality of dielectric layers (e.g., interconnect region dielectric layers) that are arranged in a direction (e.g., the z-direction) that is approximately perpendicular to the substrate layer 110. The dielectric layers may include ILD layers 116 and ESLs 118 that are arranged in an alternating manner in the z-direction. The ILD layers 116 and the ESLs 118 may extend in the x-direction and/or in the y-direction in the semiconductor device 102.

The ILD layers 116 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 116 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 118 may each include a silicon nitride (SiₓN_{y}), silicon carbide (SiC), silicon oxynitride (SiON), and/or another suitable dielectric material. In some implementations, an ILD layer 116 and an ESL 118 include different dielectric materials to provide etch selectivity to enable various structures to be formed in the interconnect layer 106.

The interconnect layer 106 includes a plurality of conductive structures. One or more of the conductive structures 120 are electrically coupled and/or physically coupled with one or more of the integrated circuit devices 112 in the device layer 104. The conductive structures 120 provide electrical routing that enables signals and/or power to be provided to and/or from the integrated circuit devices 112. The conductive structures 120 may include a combination of metallization structures and interconnect structures. The metallization structures may include trenches, metallization layers, conductive traces, and/or other types of metallization structures. The interconnect structures may include vias, plugs, interconnects, and/or another type of interconnect structures. The conductive structures 120 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the conductive structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 120 may be arranged in a plurality of layers that are arranged in a vertical manner (e.g., in the z-direction) in the interconnect layer 106. In other words, a plurality of layers of conductive structures 120 may extend above the device layer 104 in the interconnect layer 106 to facilitate electrical signals and/or power to be routed between the device layer 104 and the interconnect layer 106. The metallization structures may be arranged in metallization layers referred to as M-layers. For example, a metal-0 (M0) layer that includes a plurality of conductive structures 120 (e.g., metallization structures) may be located at the bottom of the interconnect layer 106 and may be directly coupled with the device layer 104 (e.g., with the integrated circuit devices 112 in the device layer 104). A via-1 (V1) layer that includes a plurality of conductive structures (e.g., interconnect structures) may be included above the M0 layer. A metal-1 layer (M1) layer that includes a plurality of conductive structures 120 (e.g., metallization structures) may be located above the V1 layer in the interconnect layer 106, a via-2 (V2) layer that includes a plurality of conductive structures (e.g., interconnect structures) may be included above the M1 layer, a metal-2 layer (M2) layer that includes a plurality of conductive structures 120 (e.g., metallization structures) may be located above the V2 layer, and so on.

One or more top metal layers may be included above the conductive structures 120 (e.g., the M-layers and the V-layers) in the interconnect layer 106. For example, the interconnect layer 106 may include an ESL 122, an ILD layer 124, an ESL 126, an ILD layer 128, an ESL 130, an ILD layer 132, an ESL 134, and an ILD layer 136, and may include a plurality of top vias 138 (e.g., top interconnect structures) extending through the ESL 122 and the ILD layer 124, a plurality of top metal layers 140 (e.g., top metallization structures) extending through the ESL 126 and the ILD layer 128, a plurality of top vias 142 (e.g., top interconnect structures) extending through the ESL 130 and the ILD layer 132, a plurality of testing vias 160 (e.g., testing interconnect structures) extending through the ESL 130 and the ILD layer 132, and/or a plurality of top metal layers 144 (e.g., top interconnect structures) extending through the ESL 134 and/or the ILD layer 136, among other examples. As explained in more detail herein, the testing vias 160 are used to transmit current signals during testing operations (e.g., CP testing, EVS testing, and/or WAT).

The top vias 138 and 142, and the testing vias 160 may be physically larger (e.g., may be taller in the z-direction) than the interconnect structures of the conductive structures 120. Similarly, the top metal layers 140 and 144 may be physically larger (e.g., may be taller in the z-direction) than the metallization structures of the conductive structures 120. For example, the metallization structures of the conductive structures 120 may have sub-micron z-direction heights, whereas the top metal layers 140 and 144 may have z-direction heights of approximately 1 micron or greater. However, other z-direction heights for the metallization structures of the conductive structures 120 and for the top metal layers 140 and 144 are within the scope of the present disclosure.

The physically larger sizes of the top vias 138 and 142, of the testing vias 160, and of the top metal layers 140 and 144 provide for lower sheet resistance and enable higher current signals to be handled at the top of the interconnect layer 106. The physically smaller sizes of the conductive structures 120 enable a higher density of conductive structures 120 to be included closer to the integrated circuit devices 112 in the device layer 104, which enables the integrated circuit devices 112 to be positioned closer together for higher integrated circuit device density in the device layer 104. The top metal layers 140 and 144, the top vias 138 and 142, and the testing vias 160 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the top metal layers 140 and 144, the top vias 138 and 142, and the testing vias 160. The one or more liner layers may include barrier liners, adhesion liners, and/or another type of liners. Examples of materials for the one or more liners include tantalum nitride (TaN) and/or titanium nitride (TiN), among other examples.

In some implementations, the ESLs 122, 126, 130, and 134 may include an alternating arrangement of materials. For example, the ESLs 122 and 130 may include silicon carbide (SiC), and the ESLs 126 and 134 may include a silicon nitride (SiₓN_{y} such as Si₃N₄). However, other combinations of materials for the ESLs 122, 126, 130, and 134 are within the scope of the present disclosure.

In some implementations, the ESL 122 may have a z-direction thickness that is included in a range of approximately 300 angstroms to approximately 800 angstroms. However, other values for the range are within the scope of the present disclosure. In some implementations, the ILD layer 124 may have a z-direction thickness that is included in a range of approximately 4000 angstroms to approximately 8000 angstroms. However, other values for the range are within the scope of the present disclosure. In some implementations, the ESL 126 may have a z-direction thickness that is included in a range of approximately 300 angstroms to approximately 700 angstroms. However, other values for the range are within the scope of the present disclosure. In some implementations, the ILD layer 128 may have a z-direction thickness that is included in a range of approximately 6000 angstroms to approximately 12000 angstroms. However, other values for the range are within the scope of the present disclosure. In some implementations, the ESL 130 may have a z-direction thickness that is included in a range of approximately 300 angstroms to approximately 800 angstroms. However, other values for the range are within the scope of the present disclosure. In some implementations, the ILD layer 132 may have a z-direction thickness that is included in a range of approximately 4000 angstroms to approximately 8000 angstroms. However, other values for the range are within the scope of the present disclosure. In some implementations, the ESL 134 may have a z-direction thickness that is included in a range of approximately 300 angstroms to approximately 700 angstroms. However, other values for the range are within the scope of the present disclosure. In some implementations, the ILD layer 136 may have a z-direction thickness that is included in a range of approximately 7000 angstroms to approximately 10000 angstroms. However, other values for the range are within the scope of the present disclosure.

As shown in FIG. 1, the ILD layer 132 and an ESL 134 conformally formed on the ILD layer 132 may each have a stepped profile with alternating heights in the z-direction. Different thicknesses T1 and T2 of the ILD layer 132 in the z-direction result in the stepped profile of the ILD layer 132 and the ESL 134 with alternating heights in the z-direction. The testing vias 160 may be formed through a first portion of the ILD layer 132 having a greater thickness T2 in the z-direction than a thickness T1 in the z-direction of adjacent portions of the ILD layer 132. The top surfaces of the testing vias 160 may contact a bottom surface of a first portion of the ESL 134 that is formed on the first portion of the ILD layer 132 having the greater thickness T2 in the z-direction. A top metal layer 144 may be formed through a second portion of the ILD layer 132 having the greater thickness T2 in the z-direction. The top metal layer 144 extends below a second portion of the ESL 134 that is formed on the second portion of the ILD layer 132 having the greater thickness T2 in the z-direction. The top metal layer 144 lands on and contacts two top vias 142. The height H1 of the top vias 142 in the z-direction is less than a height H2 of the testing vias 160 in the z-direction. In some implementations, the difference between the height H2 and the height H1 may be included in the range of approximately 50 angstroms to approximately 3000 angstroms. However, other values for the range are within the scope of the present disclosure.

The bonding layer 108 may be connected to the top metal layers 144 of the interconnect layer 106. The bonding layer 108 may include additional ESLs and dielectric layers, such as an ESL 146, a dielectric layer 148, an ESL 150, and/or a dielectric layer 152, among other examples. Moreover, the bonding layer 108 may include bonding vias 154 (e.g., bonding interconnect structures) that extend through the ESL 146 and/or the dielectric layer 148, and bonding pads 156 (e.g., bonding metallization structures) that extend through the ESL 150 and/or the dielectric layer 152. The bonding vias 154 may be electrically connected and/or physically connected to the top metal layers 144, and the bonding pads 156 may be electrically connected and/or physically connected to the bonding vias 154.

The ESLs 146 and 150 may each include a silicon nitride (SiₓN_{y}), silicon carbide (SiC), silicon oxynitride (SiON), and/or another suitable dielectric material. The dielectric layers 148 and 152 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material.

In some implementations, the ESL 146 may have a z-direction thickness that is included in a range of approximately 500 angstroms to approximately 1000 angstroms. However, other values for the range are within the scope of the present disclosure. In some implementations, the dielectric layer 148 may have a z-direction thickness that is included in a range of approximately 4000 angstroms to approximately 9000 angstroms. However, other values for the range are within the scope of the present disclosure. In some implementations, the ESL 150 may have a z-direction thickness that is included in a range of approximately 800 angstroms to approximately 1600 angstroms. However, other values for the range are within the scope of the present disclosure. In some implementations, the dielectric layer 152 may have a z-direction thickness that is included in a range of approximately 6000 angstroms to approximately 12000 angstroms. However, other values for the range are within the scope of the present disclosure.

The bonding vias 154 include conductive structures that are elongated primarily in the z-direction. The bonding vias 154 may electrically couple the top metal layer 144 to the bonding pads 156. The bonding pads 156 include electrically conductive pads that are used for bonding the semiconductor device 102 to another semiconductor device to form a vertically stacked semiconductor package. The bonding vias 154 and bonding pads 156 include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The bonding layer 108 further includes a bonding dielectric layer 158 around the bonding pads 156. The bonding dielectric layer 158 may also be used to bond the semiconductor device 102 to another semiconductor device to form a vertically stacked semiconductor package. Thus, the combination of the bonding pads 156 and the bonding dielectric layer 158 enables the semiconductor device 102 to be bonded to another semiconductor device in a metal-to-metal bond and in a dielectric-to-dielectric bond. The bonding dielectric layer 158 may include one or more dielectric materials such as a silicon nitride (SiₓN_{y}), silicon carbide (SiC), silicon oxynitride (SiON), and/or another suitable dielectric material. In some implementations, a z-direction thickness of the bonding dielectric layer 158 may be included in a range of approximately 500 angstroms to approximately 1000 angstroms. However, other values for the range are within the scope of the present disclosure.

As further shown in FIG. 1, the semiconductor device 102 may include one or more capacitor structures 162. A capacitor structure 162 may include a trench capacitor structure that is included in and extends through a portion of the interconnect layer 106, and/or is included in and extends through a portion of the device layer 104. The capacitor structure 162 may include a DTC structure in that the capacitor structure 162 has a high aspect ratio between a vertical (z-direction) height of the capacitor structure 162 and a lateral (x-direction) width of the capacitor structure 162. For example, the aspect ratio of the capacitor structure 162 may be greater than approximately 10:1. However, other values for the aspect ratio for the capacitor structure 162 are within the scope of the present disclosure.

As indicated above, FIG. 1 is provided as an example. Other examples may differ from what is described with regard to FIG. 1.

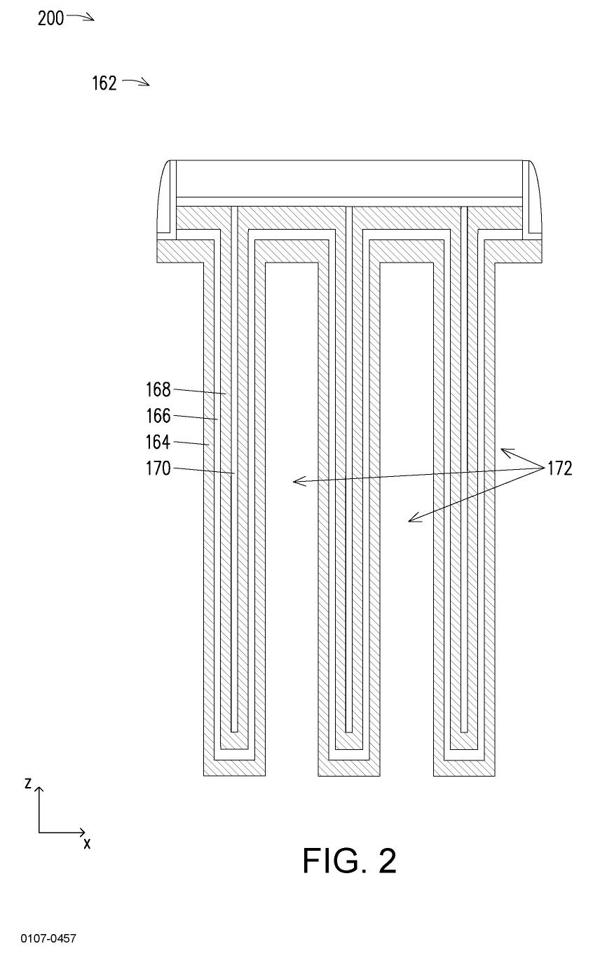

FIG. 2 is a diagram of an example implementation 200 of a capacitor structure 162 described herein. The capacitor structure 162 may be included in the interconnect layer 106 and/or the device layer 104 of the semiconductor device 102. For example, the capacitor structure 162 may be an integrated circuit device 112 included in and/or on the substrate layer 110, or part of an integrated circuit device 112 included in and/or on the substrate layer 110.

As shown in FIG. 2, the capacitor structure 162 includes a plurality of conformal layers, including a bottom electrode layer 164, an insulator layer 166 on the bottom electrode layer 164, and a top electrode layer 168 on the insulator layer 166. Thus, the insulator layer 166 is located between the bottom electrode layer 164 and the top electrode layer 168, which enables the capacitor structure 162 to store an electrical charge based on the capacitance between the bottom electrode layer 164 and the top electrode layer 168. A dielectric filler 170 may be included between segments of the top electrode layer 168 to electrically isolate the segments of the top electrode layer 168. However, in other implementations, the dielectric filler 170 is omitted.

The bottom electrode layer 164, the insulator layer 166, and the top electrode layer 168 correspond to a metal-insulator-metal (MIM) stack of the capacitor structure 162. Thus, the capacitor structure 162 may also be referred to as an MIM capacitor structure. The bottom electrode layer 164 (also referred to as a capacitor bottom metal (CBM)) and the top electrode layer 168 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), tantalum (Ta), aluminum (Al), copper (Cu), gold (Au), titanium nitride (TiN), and/or tantalum nitride (TaN), among other examples. In some implementations, the bottom electrode layer 164 and the top electrode layer 168 include the same material or the same material composition. In some implementations, the bottom electrode layer 164 and the top electrode layer 168 include different materials or different material compositions.

The insulator layer 166 may include one or more electrically insulating materials. In some implementations, the insulator layer 166 includes one or more low-k dielectric materials such as silicon oxide (SiOₓ such as SiO₂). Additionally and/or alternatively, the insulator layer 166 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 166 is a multiple-layer stack that includes a plurality of dielectric layers. For example, the insulator layer 166 may include a ZrO₂/Al₂O₃/ZrO₂ (ZAZ) layer stack.

As further shown in FIG. 2, the capacitor structure 162 may include a deep trench structure 172 that vertically extends (e.g., in the z-direction) through a plurality of dielectric layers in the interconnect layer 106 and/or device layer 104. For example, the deep trench structure 172 may extend through one or more ILD layers 116, one or more ESLs 118, among other examples. In the example illustrated in FIG. 1, the top of the capacitor structure 162 (e.g., the top electrode layer 168) is physically coupled and/or electrically coupled to a top via 138 in the interconnect layer 106.

As further shown in FIG. 2, the bottom electrode layer 164, the insulator layer 166, and/or the top electrode layer 168 may be conformal layers that extend into the deep trench structure 172. In particular, the bottom electrode layer 164, the insulator layer 166, and/or the top electrode layer 168 may extend along the sidewalls and the bottom surfaces of the deep trench structure 172. The portions of the bottom electrode layer 164 at the bottom of the capacitor structure 162 may be on, and in physical contact with, an underlying conductive structure 120 at the bottom of the capacitor structure 162. Thus, the bottom electrode layer 164 may be electrically connected to the conductive structure 120 in the interconnect layer 106 or to a conductive structure in the device layer 104.

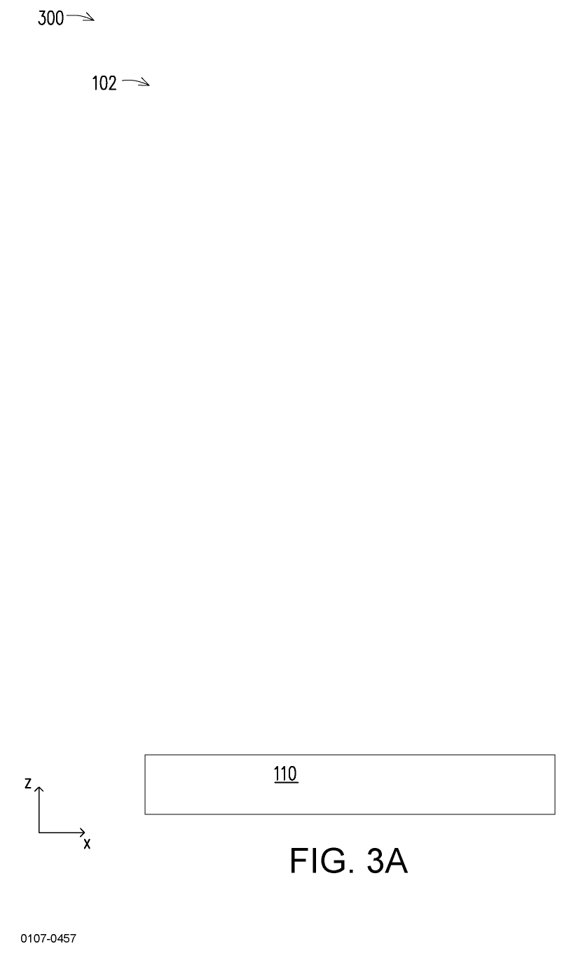

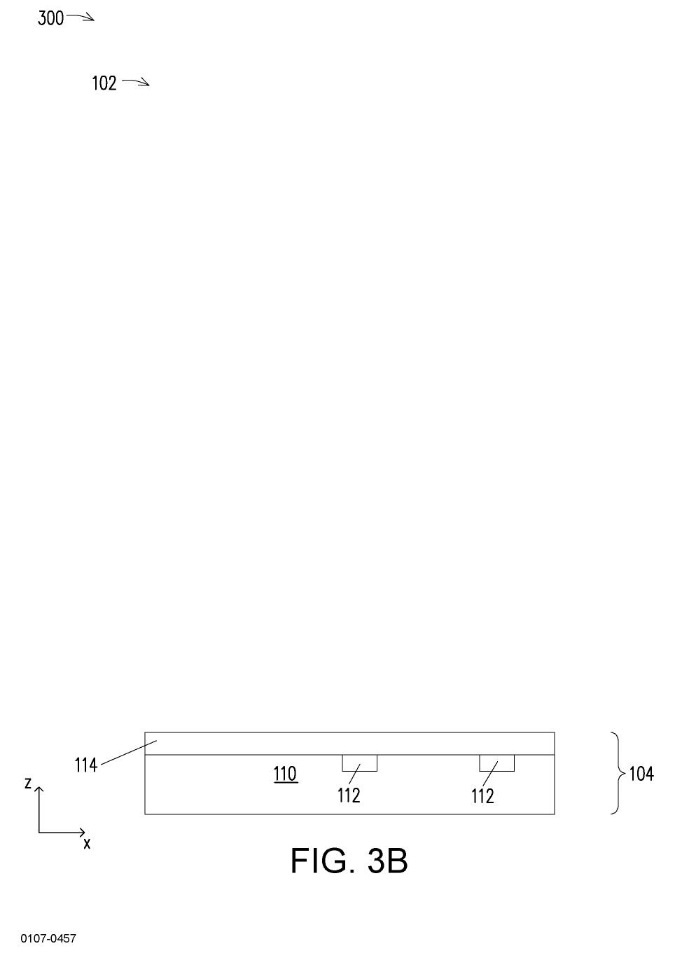

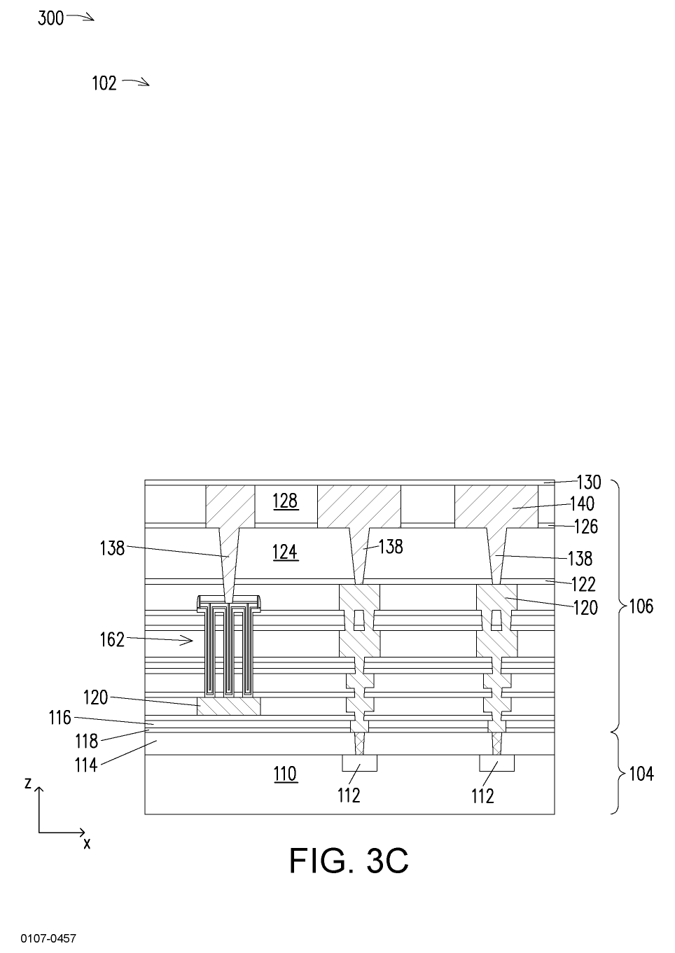

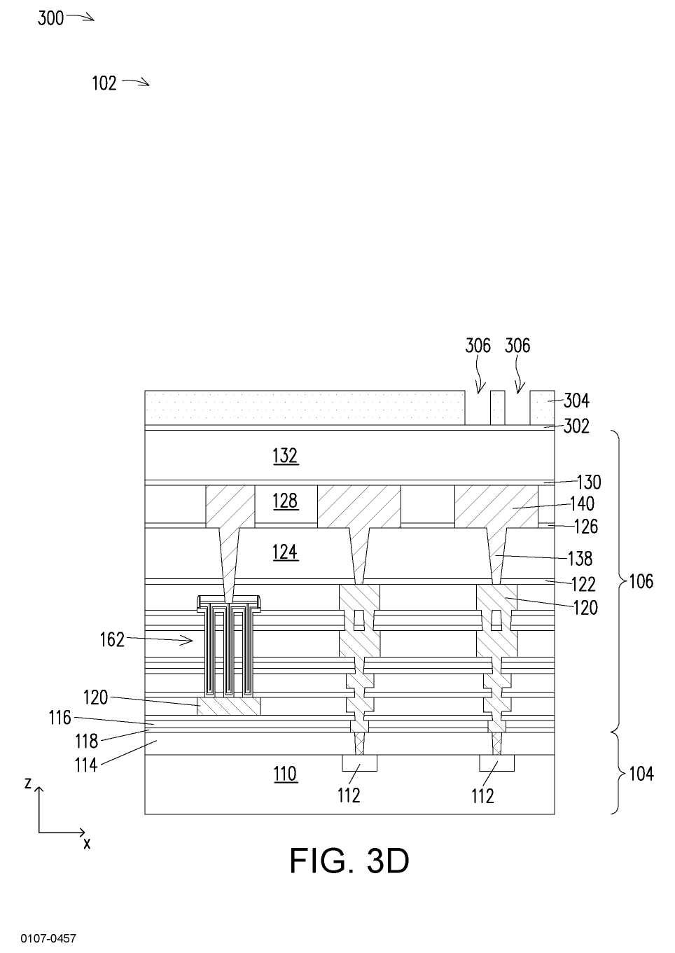

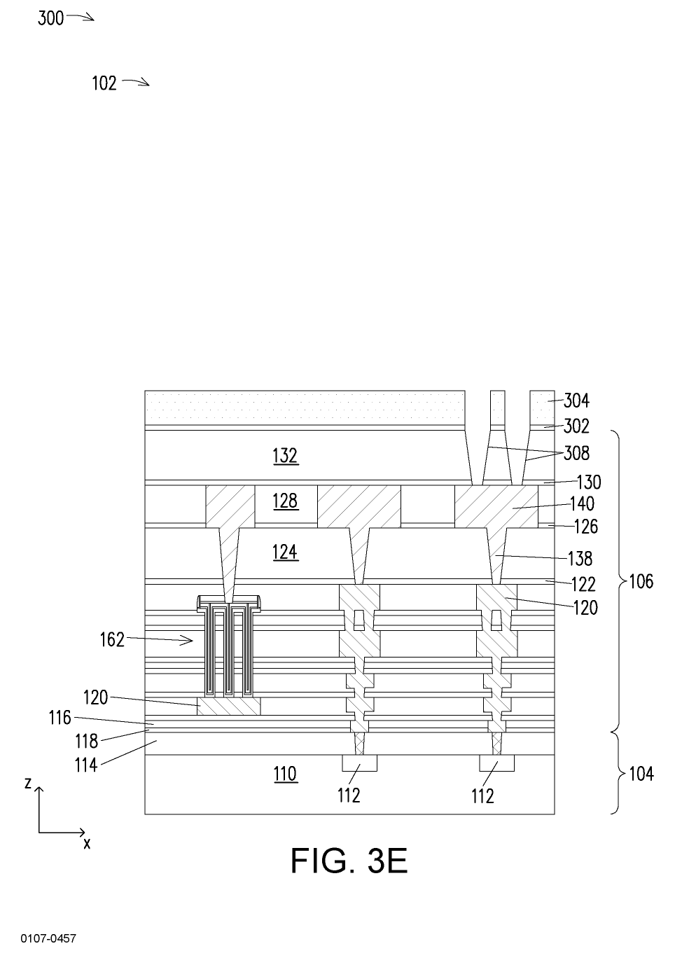

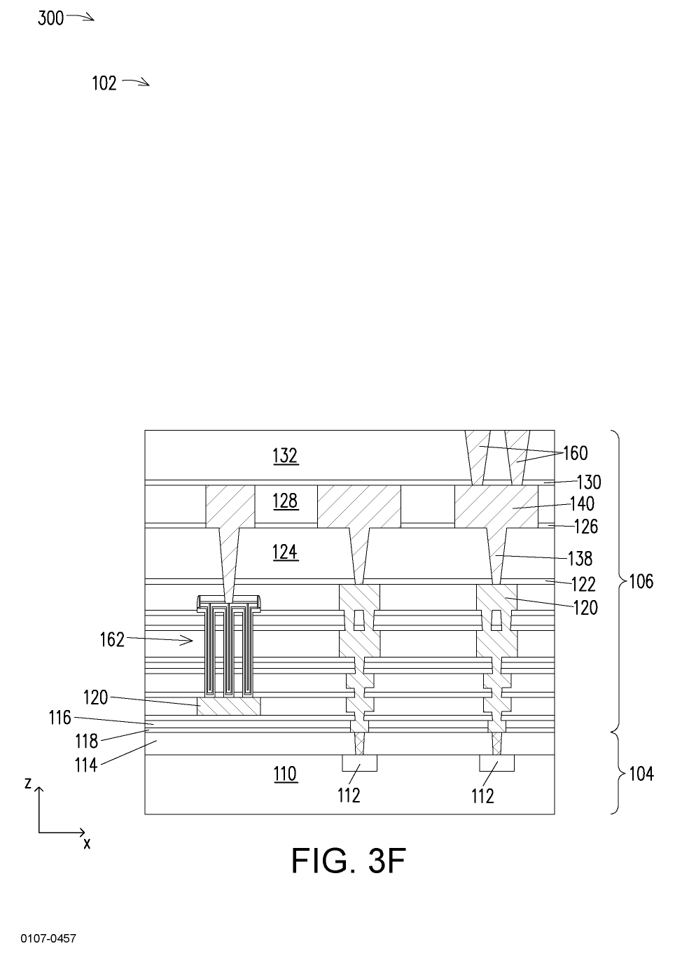

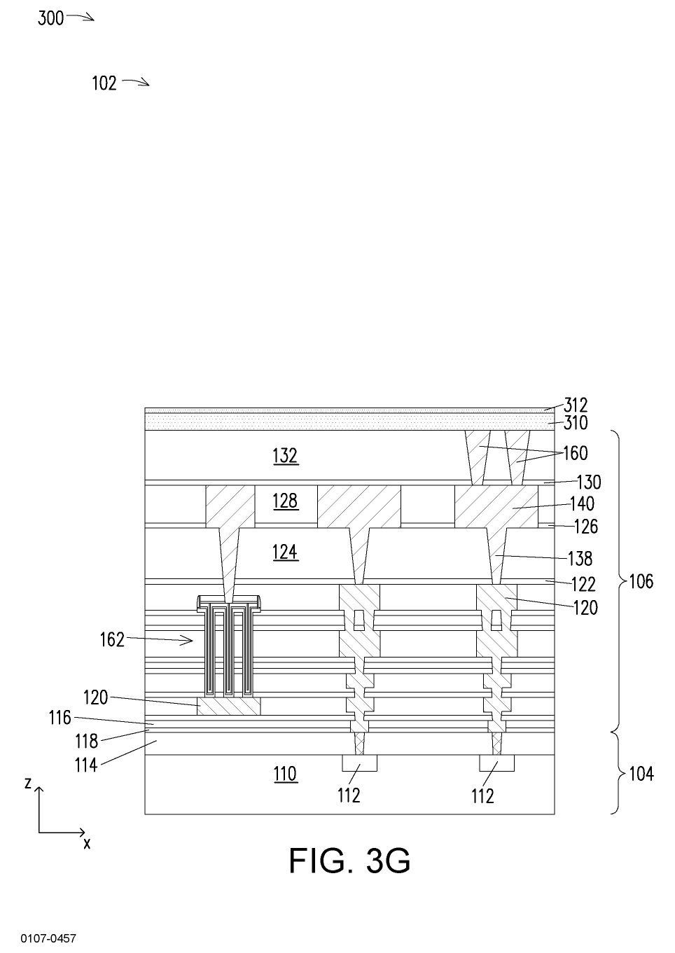

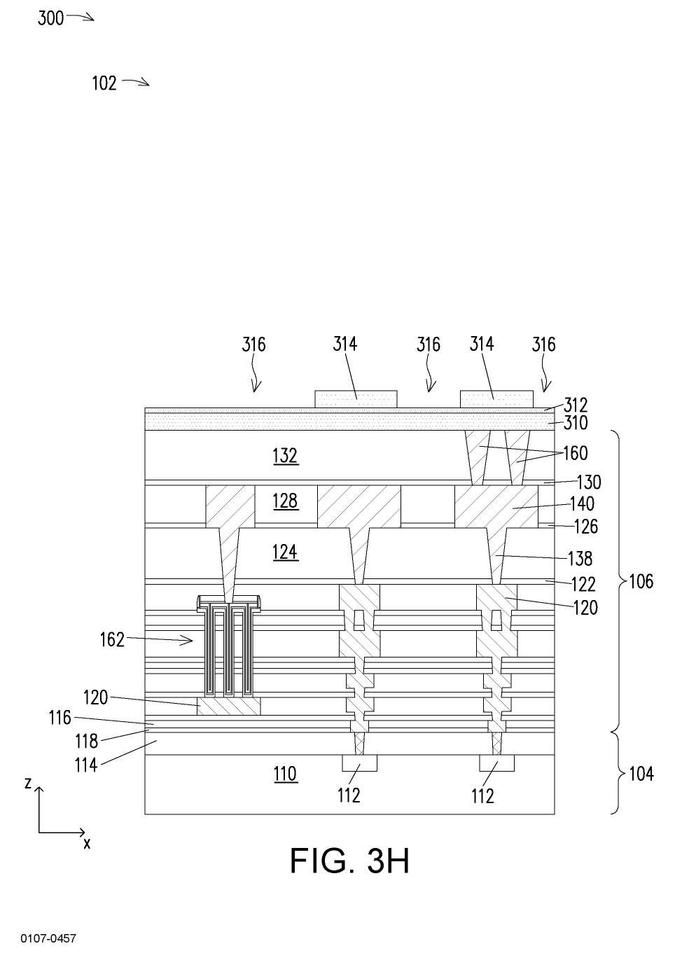

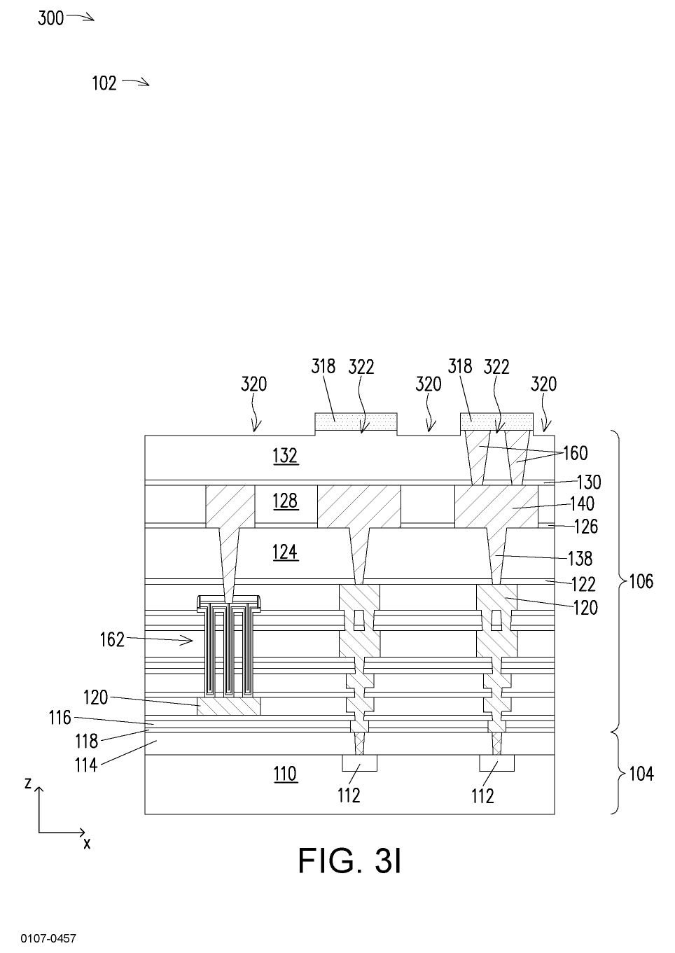

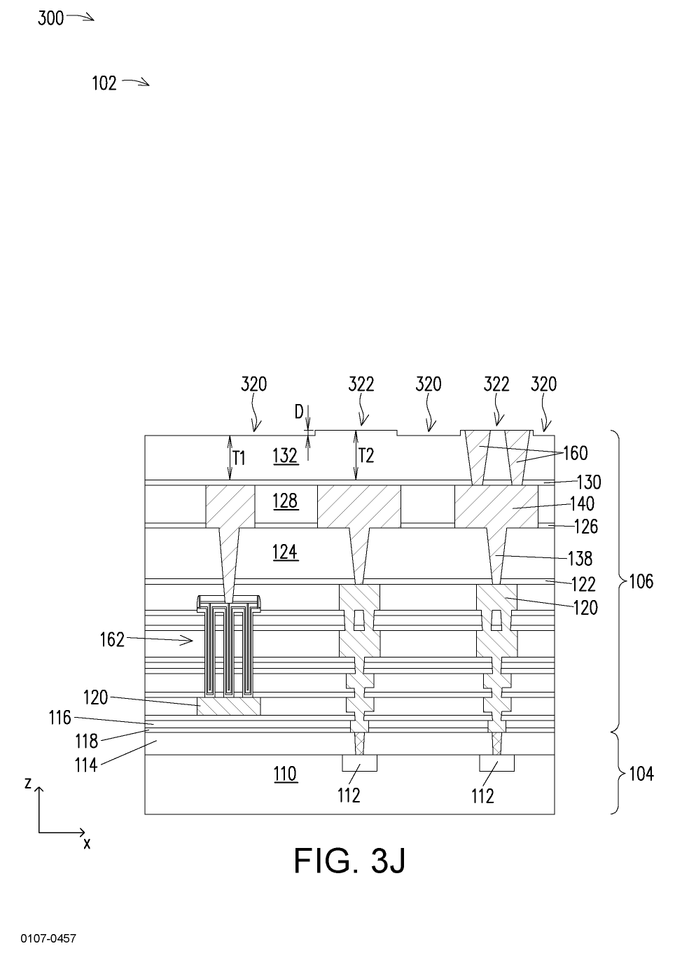

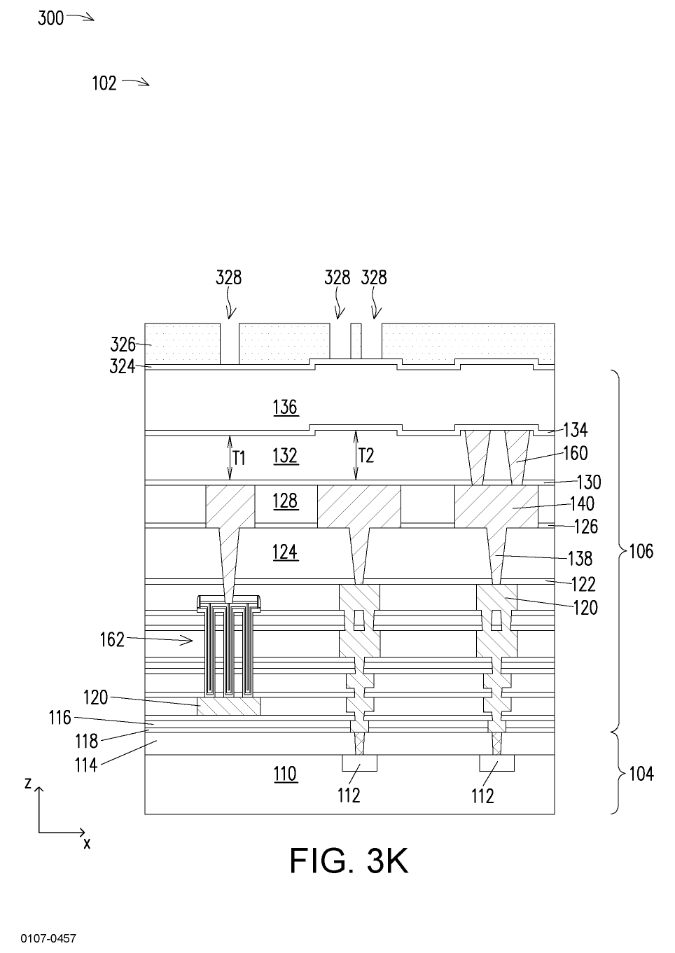

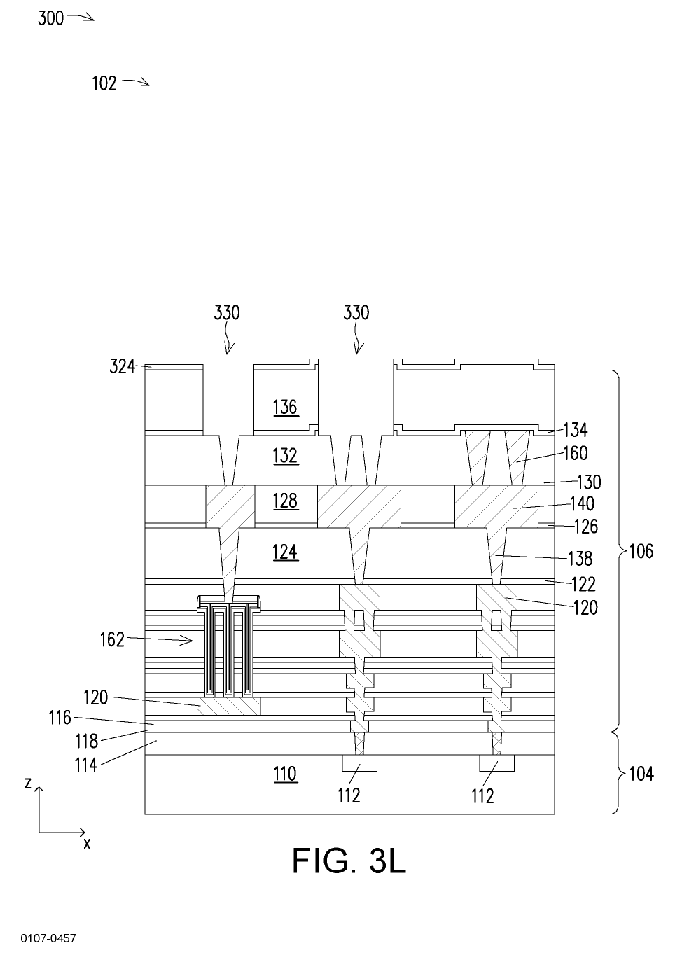

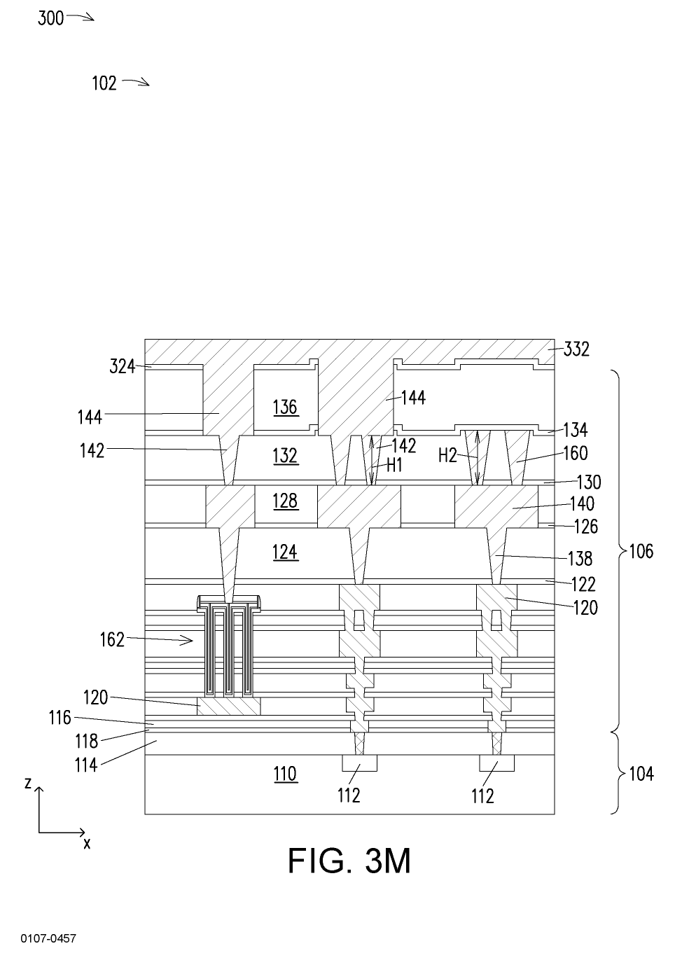

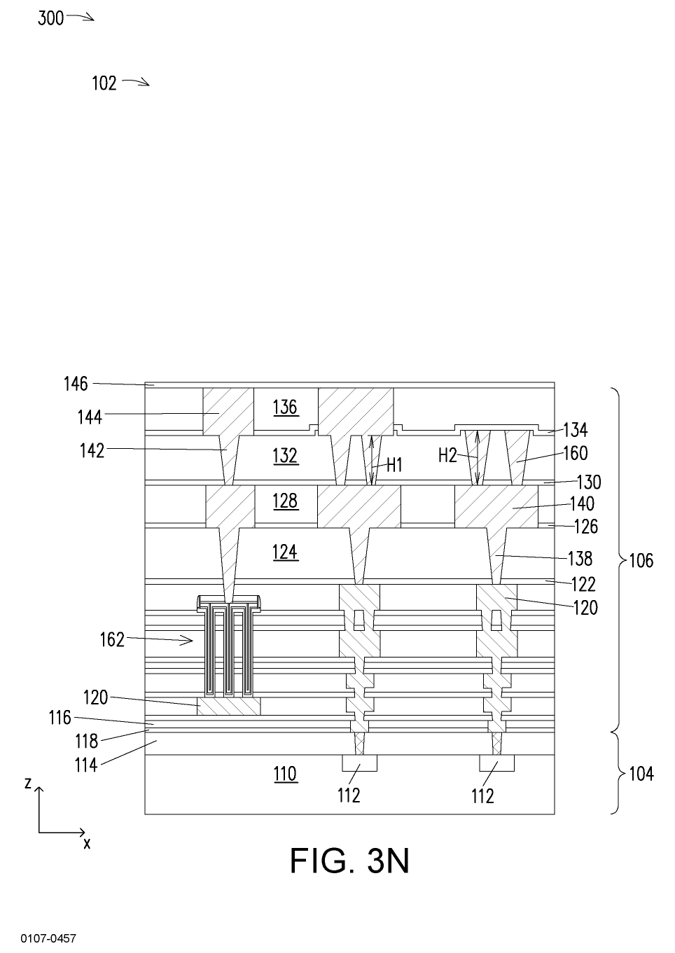

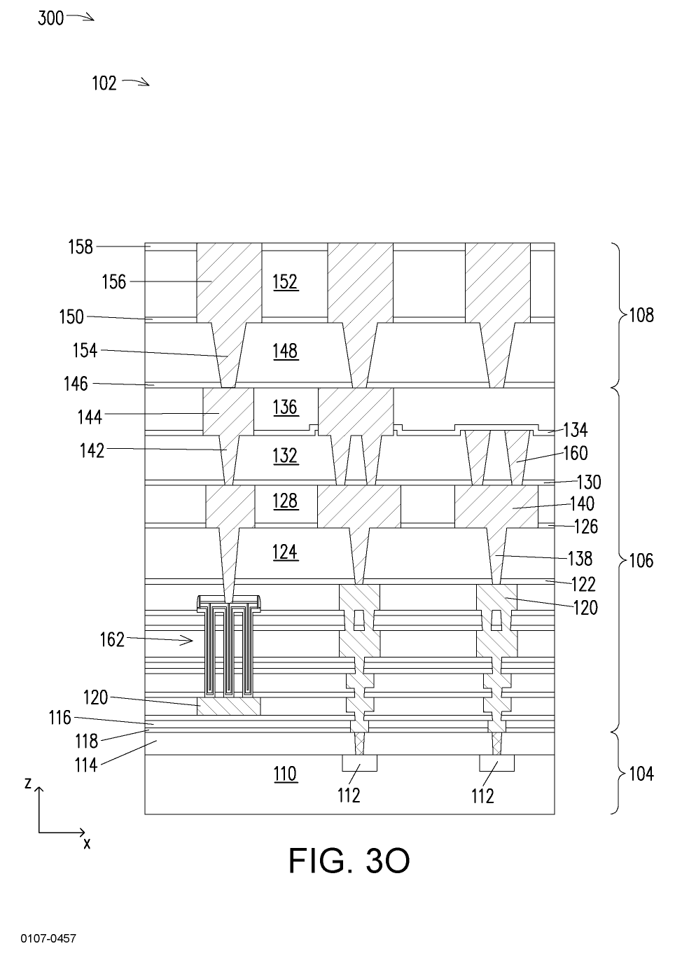

FIGS. 3A-3O are diagrams of an example implementation 300 of forming a semiconductor device 102 described herein. In particular, the example implementation 300 includes an example of forming the example implementation 100 of the semiconductor device 102 illustrated in FIG. 1. In some implementations, one or more of the semiconductor processing operations described in connection with FIGS. 3A-3O may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 3A, the substrate layer 110 may be provided. The substrate layer 110 may be provided in the form of a semiconductor wafer such as a silicon (Si) wafer, an SOI wafer, and/or another type of semiconductor work piece. The semiconductor device 102 may be formed on the semiconductor wafer with other semiconductor devices.

As shown in FIG. 3B, the integrated circuit devices 112 may be formed in and/or on the substrate layer 110 in the device layer 104 of the semiconductor device 102. One or more semiconductor processing tools may be used to form one or more portions of the integrated circuit devices 112. For example, an ion implantation tool may be used to dope one or more regions in the substrate layer 110 with one or more types of dopants to form well regions, implant regions, and/or other types of doped regions in the substrate layer 110 for the integrated circuit devices 112. As another example, a deposition tool may be used to perform various deposition operations to deposit layers and/or structures of the integrated circuit devices 112, and/or to deposit photoresist layers for etching the substrate layer 110 and/or portions of the deposited layers. As another example, an exposure tool may be used to expose the photoresist layers to form patterns in the photoresist layers. As another example, a developer tool may be used to develop the patterns in the photoresist layers. As another example, an etch tool may be used to etch the substrate layer 110 and/or portions of the deposited layers to form the integrated circuit devices 112. As another example, a planarization tool may be used to planarize portions of the integrated circuit devices 112. As another example, a plating tool may be used to deposit metal structures and/or layers of the integrated circuit devices 112.

As further shown in FIG. 3B, a deposition tool is used to deposit the dielectric layer 114 over and/or on the substrate layer 110 and over and/or on the integrated circuit devices 112. A deposition tool may be used to deposit the dielectric layer 114 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation, such as a chemical mechanical planarization (CMP) operation, to planarize the dielectric layer 114 after the dielectric layer 114 is deposited.

As shown in FIG. 3C, a first portion of the interconnect layer 106 of the semiconductor device 102 is formed above the dielectric layer 114. One or more deposition tools are used to deposit alternating layers of ILD layers 116 and ESLs 118 in the first portion of the interconnect layer 106 of the semiconductor device 102. In this way, the ILD layers 116 and ESLs 118 may be arranged in the z-direction in the semiconductor device 102. One or more deposition tools may be used to deposit each of the ILD layers 116 and each of the ESLs 118 using a PVD technique, an ALD technique, a CVD technique, an oxidation technique, and/or another suitable deposition technique. In some implementations, a planarization tool may be used to planarize the ILD layers 116 and/or the ESLs 118 after the ILD layers 116 and/or the ESLs 118 are deposited.

Prior to formation of the interconnect layer 106, contacts of the integrated circuit devices 112 may be formed through the dielectric layer 114. The contacts may be formed in recesses in the dielectric layer 114. In some implementations, a pattern in a photoresist layer is used to etch the dielectric layer 114 to form the recesses. In these implementations, a deposition tool may be used to form the photoresist layer on the dielectric layer 114. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 114 based on a pattern to form the recesses.

The contacts may be formed in the recesses. In some implementations, a contact (e.g., a gate contact) is formed on a gate structure of an integrated circuit device 112. In some implementations, a contact (e.g., a source/drain contact) is formed on a source/drain region of an integrated circuit device 112. A deposition tool may be used to deposit the material of the contacts in the recesses using a CVD technique, a PVD technique, an ALD technique, an electroplating technique (e.g., an electro-chemical plating technique), and/or another suitable deposition technique. The material of the contacts may be deposited in one or more deposition operations. In some implementations, a seed layer is first deposited, and the material of the contacts is deposited on the seed layer. In some implementations, a planarization tool is used to perform a planarization operation (e.g., a CMP operation) to planarize the contacts after the contacts are deposited such that the tops of the contacts are approximately co-planar with the top of the dielectric layer 114.

As further shown in FIG. 3C, a deposition tool, an exposure tool, a developer tool, an etch tool, a planarization tool, a plating tool, and/or another semiconductor processing tool may be used to perform various operations to form the conductive structures 120 in the first portion of the interconnect layer 106 of the semiconductor device 102. In some implementations, the first portion of the interconnect layer 106 may be formed in a plurality of layers. For example, an ILD layer 116 and an ESL 118 may be formed (e.g., using one or more deposition tools and/or one or more planarization tools), recesses may be formed in and/or through the ILD layer 116 and the ESL 118 (e.g., using an exposure tool, a developer tool, and/or an etch tool), and a first layer (e.g., the M0 layer) of conductive structures 120 (e.g., of metallization structures) may be formed in the ILD layer 116 and the ESL 118 (e.g., using one or more deposition tools and/or one or more planarization tools). Another ILD layer 116 and another ESL 118 may be formed, and a second layer (e.g., the V0 layer) of conductive structures 120 (e.g., of interconnect structures) may be formed in the ILD layer 116 and the ESL 118. Additional layers of conductive structures 120 may be formed in the interconnect layer 106 a similar manner.

One or more deposition tools may be used to deposit the conductive structures 120 using a PVD technique, an ALD technique, a CVD technique, an electroplating technique (e.g., an electro-chemical plating technique), and/or another suitable deposition technique. In some implementations, a planarization tool may be used to planarize the conductive structures 120 after the conductive structures 120 are deposited.

As further shown in FIG. 3C, a deposition tool, an exposure tool, a developer tool, an etch tool, a planarization tool, a plating tool, and/or another semiconductor processing tool may be used to perform various operations to form the capacitor structure 162 on a conductive structure 120 in the first portion of the interconnect layer 106 of the semiconductor device 102. A patterning stack may be formed above a portion of an ESL 118 or ILD layer 116. The patterning stack may include a plurality of masking layers that are used to form a recess in which a capacitor structure 162 may be formed in the semiconductor device 102. The masking layers may include an advanced patterning film (APF) layer, a bottom anti-reflective coating (BARC) on the APF layer, and/or a photoresist layer on the BARC, among other examples. The masking layers of the patterning stack may be selected to form the recess for the capacitor structure 162 in a highly controlled manner to achieve substantially vertical sidewalls (and thus, a high aspect ratio) for the capacitor structure 162. The APF layer may include an amorphous carbon material and/or another suitable material. The BARC may include silicon oxynitride (SiON), a polymer, and/or another suitable material. A deposition tool may be used to deposit the APF layer, the BARC, and/or the photoresist layer using a PVD technique, a CVD technique, an ALD technique, a spin-coating technique, and/or another suitable deposition technique.

An etch tool may be used to etch through portions of one or more ESLs 118, and/or through portions of one or more ILD layers 116 to form a plurality of recesses to an underlying conductive structure 120 in the interconnect layer 106. The recesses may include a plurality of interconnected trenches. In some implementations, a pattern is formed in the photoresist layer, and the pattern is used to form the recesses. An exposure tool may be used to expose the photoresist layer to a radiation source in order to pattern the photoresist layer. A developer tool may be used to develop and remove portions of the photoresist layer to expose the pattern. An etch tool may be used to etch the BARC and/or the APF layer based on the pattern to transfer the pattern to the BARC and/or to the APF layer. An etch tool may be used to etch through the portions of the one or more ESLs 118, and/or through the portions of the one or more ILD layers 116 based on the pattern in the photoresist layer, in the BARC, and/or in the APF layer to form the recesses. In some implementations, the etch operation to form the recesses includes a dry etch operation (e.g., a plasma-based etch operation, a gas-based etch operation), a wet chemical etch operation, and/or another type of etch operation.

In some implementations, a deep reactive ion etch technique (sometimes referred to as a “BOSCH” etch technique) may be used to achieve the high aspect ratio for the recesses. A deep reactive ion etch technique is a cyclic etch technique in which a plurality of deposition and etch cycles are performed using protective liners to minimize lateral etching. In some implementations, a photoresist removal tool may be used to remove the remaining portions of the photoresist layer (e.g., using a chemical stripper, plasma ashing, and/or another technique). Moreover, an etch tool and/or a planarization tool may be used to remove the remaining portions of the BARC and/or the remaining portions of the APF layer.

The bottom electrode layer 164, the insulator layer 166, the top electrode layer 168, and the dielectric filler 170 may be formed in the recesses. The bottom electrode layer 164 may be conformally deposited on the sidewalls and on the bottom surface (which corresponds to the top surface of the conductive structure 120 exposed through the recesses) of the recesses. In some implementations, a conformal CVD technique and/or an ALD technique is used to deposit the bottom electrode layer 164.

The insulator layer 166 may be deposited on the bottom electrode layer 164. Thus, the insulator layer 166 is deposited on the sidewalls and on the bottom surface (which corresponds to the top surface of the conductive structure 120 exposed through the recesses) of the recesses. In some implementations, a deposition tool is used to conformally deposit the insulator layer 166 using a conformal CVD technique and/or an ALD technique.

The top electrode layer 168 may be deposited on the insulator layer 166. Thus, the top electrode layer 168 is deposited on the sidewalls and on the bottom surface (which corresponds to the top surface of the conductive structure 120 exposed through the recesses) of the recesses. In some implementations, a deposition tool is used to conformally deposit the top electrode layer 168 using a conformal CVD technique and/or an ALD technique.

The dielectric filler 170 may be deposited on the top electrode layer 168 such that the dielectric filler 170 fills the remaining area of the recesses. In some implementations, a deposition tool is used to deposit the dielectric filler 170 using a PVD technique, a CVD technique, an ALD technique, and/or another suitable deposition technique.

Capping layers may be formed above the recesses. For example, capping layers may be formed over the top surface of an ESL 118. A deposition tool may be used to deposit the capping layers using a PVD technique, an ALD technique, a CVD technique, an oxidation technique, and/or another suitable deposition technique. In some implementations, a planarization tool may be used to perform a planarization operation (e.g., a CMP operation) to planarize the capping layers after the capping layers are deposited.

An etch operation may be performed to define the capping layers, the top electrode layer 168, and/or the insulator layer 166 of the capacitor structure 162. An etch tool may be used to etch the capping layers, the top electrode layer 168, and/or the insulator layer 166. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the patterned masking layers (e.g., using a chemical stripper, plasma ashing, and/or another technique).

Sidewall spacers are formed on the ends of the insulator layer 166, on the ends of the top electrode layer 168, and/or on the ends of the capping layers. A deposition tool may be used to deposit the sidewall spacers using a PVD technique, an ALD technique, a CVD technique, an oxidation technique, and/or another suitable deposition technique. The sidewall spacers may be deposited in one or more deposition operations.

As further shown in FIG. 3C, the ESLs 122, 126, and 130 may be formed in the interconnect layer 106, and the ILD layers 124 and 128 may be formed in the interconnect layer 106. One or more deposition tools may be used to deposit the ESLs 122, 126, and 130, and the ILD layers 124 and 128 using a PVD technique, an ALD technique, a CVD technique, an oxidation technique, and/or another suitable deposition technique. In some implementations, a planarization tool may be used to planarize the ESLs 122, 126, 130, and the ILD layers 124 and 128.

As further shown in FIG. 3C, a deposition tool, an exposure tool, a developer tool, an etch tool, a planarization tool, a plating tool, and/or another semiconductor processing tool may be used to perform various operations to form the top vias 138 and the top metal layers 140 in the first portion of the interconnect layer 106 of the semiconductor device 102. In some implementations, the ESL 122 and the ILD layer 124 may be formed, recesses may be formed in and/or through the ESL 122 and the ILD layer 124 (e.g., using an exposure tool, a developer tool, and/or an etch tool), and the top vias 138 may be formed in the recesses (e.g., using one or more deposition tools and/or one or more planarization tools). In some implementations, the ESL 126 and the ILD layer 128 may be formed, recesses may be formed in and/or through the ESL 126 and the ILD layer 128 (e.g., using an exposure tool, a developer tool, and/or an etch tool), and the top metal layers 140 may be formed in the recesses (e.g., using one or more deposition tools and/or one or more planarization tools).

An ILD layer 116 encapsulates the top of the capacitor structure 162. A top via 138 may be formed through the ILD layer 124, through the ESL 122, and through an ILD layer 116 such that the top via 138 lands on the top electrode layer 168 of the capacitor structure 162. The top via 138 electrically connects the capacitor structure 162 to a top metal layer 140 and to other structures in the semiconductor device 102.

As shown in FIG. 3D, the ILD layer 132 is formed on the ESL 130. As shown in FIG. 3D, masking layers may be formed on the ILD layer 132. For example, a dielectric masking layer 302 may be formed on the ILD layer 132. The dielectric masking layer 302 may include a silicon oxynitride material (SiON) and/or another suitable dielectric material. A deposition tool may be used to deposit the dielectric masking layer 302 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 302 after the dielectric masking layer 302 is deposited.

A photoresist layer 304 may be formed above the dielectric masking layer 302, and a pattern 306 may be formed in the photoresist layer 304. A deposition tool may be used to form the photoresist layer on the dielectric masking layer 302 (e.g., using a spin-coating technique or another suitable deposition technique). In some implementations, a bottom antireflective coating (BARC) is first deposited on the dielectric masking layer 302, and then the photoresist layer 304 is deposited onto the BARC. An exposure tool may be used to expose the photoresist layer 304 to a radiation source to pattern the photoresist layer 304. A developer tool may be used to develop and remove portions of the photoresist layer 304 to expose the pattern 306.

As shown in FIG. 3E, an etch tool may be used to etch the dielectric masking layer 302 based on the pattern 306 in the photoresist layer 304, to transfer the pattern 306 to the dielectric masking layer 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 302 compared to the material of the underlying ILD layer 132. Thus, the etch operation may stop on the ILD layer 132 with minimal etching to the ILD layer 132.

Another etch operation may be performed to etch through the ILD layer 132, and through the ESL 130 to form recesses 308, where bottom surfaces of the recesses 308 expose portions of top surfaces of the underlying top metal layer 140. The etch operation may include, for example, a gas-based etch operation in which a different type of etchant is used, as compared to the etchant that was used to transfer the pattern 306 to the dielectric masking layer 302. Thus, the semiconductor device 102 may be transferred from a first etch tool (in which the pattern 306 was transferred to the dielectric masking layer 302) to a second etch tool (in which the ILD layer 132, and the ESL 130 are etched) using a wafer/die transport tool to reduce the likelihood of cross-contamination between the first and second etch tools. Alternatively, an etch tool that has multiple processing chambers (e.g., a cluster tool) may be used, and the semiconductor device 102 may be transferred between processing chambers of the etch tool for etching using different types of etchants.

As shown in FIG. 3F, one or more deposition tools may be used to deposit the testing vias 160 using a PVD technique, an ALD technique, a CVD technique, an electroplating technique (e.g., an electro-chemical plating technique), and/or another suitable deposition technique. In some implementations, a planarization tool may be used to planarize the testing vias 160 and a top surface of the ILD layer 132 to remove remaining portions of the photoresist layer 304, the dielectric masking layer 302, and/or the conductive material of the testing vias 160 on the top surface of the ILD layer 132 after the testing vias 160 are deposited.

As shown in FIG. 3G, a metal layer 310 is formed over and/or on the ILD layer 132, including the testing vias 160 formed in the ILD layer 132. A deposition tool and/or a plating tool may be used to deposit the metal layer 310 using a PVD technique, an ALD technique, a CVD technique, an oxidation technique, an electroplating technique (e.g., an electro-chemical plating technique), and/or another suitable deposition technique. In some implementations, the planarization tool may be used to planarize the metal layer 310 after the metal layer 310 is deposited. In some implementations, a seed layer is first deposited, and the metal layer 310 is deposited on the seed layer. The metal layer 310 includes aluminum (Al), aluminum copper (AlCu), tungsten (W), cobalt (Co), ruthenium (Ru), titanium (Ti), gold (Au), and/or another conductive material.

As further shown in FIG. 3G, a capping layer 312 may be formed over and/or on the metal layer 310. A deposition tool may be used to deposit the capping layer 312 using a PVD technique, an ALD technique, a CVD technique, an oxidation technique, and/or another suitable deposition technique. In some implementations, the planarization tool may be used to planarize the capping layer 312 after the capping layer 312 is deposited. The capping layer 312 may include silicon nitride (SixNy), silicon oxynitride (SiON), and/or another suitable capping material. The capping layer 312 may be used to protect a portion of the metal layer 310 from etching to enable a sacrificial test pad to be formed from the metal layer 310.

As shown in FIGS. 3H and 3I, a pattern 316 in a photoresist layer 314 is used to etch the capping layer 312 and the metal layer 310 to form sacrificial test pads 318 on the ILD layer 132. The sacrificial test pads 318 may be formed on the ILD layer 132 by removing portions of the metal layer 310 using the pattern 316 in the photoresist layer 314, where a remaining portion of the metal layer 310 corresponds to the sacrificial test pads 318. In these implementations, a deposition tool is used to form the photoresist layer 314 on the capping layer 312. An exposure tool is used to expose the photoresist layer 314 to a radiation source to pattern the photoresist layer 314. A developer tool is used to develop and remove portions of the photoresist layer 314 to expose the pattern. An etch tool may be used to etch the capping layer 312 and the metal layer 310 based on the pattern 316 in the photoresist layer 314 to form the sacrificial test pads 318 from the metal layer 310. The etch operation removes exposed portions of the metal layer 310, which then exposes underlying portions of the ILD layer 132. The etch operation further removes exposed portions of the ILD layer 132 adjacent to the sacrificial test pads 318 to form a plurality of recessed portions 320 in the ILD layer 132. The sacrificial test pads 318 are on raised portions 322 of the ILD layer 132 adjacent to the recessed portions 320. In some implementations, the etch operation includes a wet etch operation. For example, an etch tool may be used to etch exposed portions of the metal layer 310 in a wet etch operation, where tetramethyl ammonium hydroxide (TMAH) is used as the etchant to remove portions of the metal layer 310 to form the sacrificial test pads 318. Alternatively, the etch operation includes a dry etch operation such as a plasma-based etch operation. The dry etch operation may enable an anisotropic etch to be performed to form the sacrificial test pads 318 such that the sacrificial test pads 318 have substantially vertical sidewalls. However, other etch techniques for forming the sacrificial test pads 318 are within the scope of the present disclosure. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the metal layer 310 based on a pattern.

In some implementations, a thickness of the sacrificial test pads 318 in the z-direction is greater than approximately 500 angstroms. If the thickness of the sacrificial test pads 318 is less than approximately 500 angstroms, this may result in high resistance induced electrical voltage stress (EVS), causing a high voltage (IR) drop across the sacrificial test pads 318. The high voltage (IR) drop may cause the testing results to be inaccurate due to tested circuits not receiving enough voltage, increased power consumption of the tested circuits, increased heat generation, and/or other types of errors. Other values for the thickness of the sacrificial test pads 318 are within the scope of the present disclosure.

Using the sacrificial test pads 318, testing operations including, for example, circuit probe (CP) testing, wafer acceptance testing (WAT), and/or electrical voltage stress (EVS) testing, can be performed on the semiconductor device 102. The testing operations may confirm whether integrated circuit devices 112 (e.g., DTC structures, logic devices, and/or other devices in the device layer 104), and/or whether devices in the interconnect layer 106 (e.g., capacitor structure 162) are operational or may be experiencing operational issues. The testing operations may include applying high voltages and/or other current-based signals to the sacrificial test pads 318 through test probes contacting surfaces (e.g., top surfaces) of the sacrificial test pads 318. The high voltages and/or other current-based signals may be transmitted to different circuits and/or devices 112 of the semiconductor device 102 through the test vias 160, other test vias (not shown), top metal layers 140, top vias 138, and/or conductive structures 120 to discover weak chips prior to performing wafer bonding. The application of the test probes to the sacrificial test pads 318 may form marks, recesses, protrusions, and/or other imperfections in the sacrificial test pads 318.

As shown in FIG. 3J, following testing operations, in order to avoid any adverse effects (e.g., uneven surfaces, weak bonds, increased oxidation, and/or etching contamination) that may result from any imperfections in the sacrificial test pads 318, the sacrificial test pads 318 are removed. In some implementations, the sacrificial test pads 318 are removed in an etch operation. For example, an etch tool may be used to etch sacrificial test pads 318 in a wet etch operation, where tetramethyl ammonium hydroxide (TMAH) is used as the etchant to selectively etch the material (e.g., aluminum) of the sacrificial test pads 318. As a result of the etching, the top surfaces of the test vias 160, and the top surfaces of the ILD layer 132, including the top surfaces of the recessed portions 320 and the top surfaces of the raised portions 322, are exposed. As can be seen in FIG. 3J, the remaining portion of the ILD layer 132 has a stepped (e.g., non-planar) profile with alternating heights in the z-direction based on a thickness T1 corresponding to the recessed portions 320, and a thickness T2 corresponding to the raised portions 322, where the thickness T2 is greater than the thickness T1. In some implementations, a depth D of the recessed portions 320 may be greater than approximately 5 nanometers. However, other values for the depth of the recessed portions 320 are within the scope of the present disclosure.

As shown in FIG. 3K, the ESL 134 is deposited on the top surfaces of the test vias 160, and on the top surfaces of the ILD layer 132, including on the top surfaces of the recessed portions 320 and on the top surfaces of the raised portions 322. As a result, like the ILD layer 132, the ESL 134 has a stepped (e.g., non-planar) profile with alternating heights in the z-direction based on the thickness T1 corresponding to the recessed portions 320, and the thickness T2 corresponding to the raised portions 322. A deposition tool may be used to conformally deposit the ESL 134 using a PVD technique, an ALD technique, a CVD technique, an oxidation technique, and/or another suitable deposition technique, so that the ESL 134 conforms to the stepped profile of the ILD layer 132.

Following deposition of the ESL 134, the ILD layer 136 is deposited on top surfaces of the ESL 134. Like the ILD layer 132 and the ESL 134, the ILD layer 136 also has a stepped (e.g., non-planar) profile with alternating heights in the z-direction based on the thickness T1 corresponding to the recessed portions 320, and the thickness T2 corresponding to the raised portions 322. A deposition tool may be used to conformally deposit the ILD layer 136 using a PVD technique, an ALD technique, a CVD technique, an oxidation technique, and/or another suitable deposition technique, so that the ILD layer 136 conforms to the stepped profile of the ESL 134 and covers a top surface of the ESL 134.

Following deposition of the ILD layer 136, a dielectric masking layer 324 is deposited on top surfaces of the ILD layer 136. Like the ILD layers 132 and 136, and the ESL 134, the ILD layer 136 also has a stepped (e.g., non-planar) profile with alternating heights in the z-direction based on the thickness T1 corresponding to the recessed portions 320, and the thickness T2 corresponding to the raised portions 322. A deposition tool may be used to conformally deposit the dielectric masking layer 324 using a PVD technique, an ALD technique, a CVD technique, an oxidation technique, and/or another suitable deposition technique, so that the dielectric masking layer 324 conforms to the stepped profile of the ILD layer 136.

A photoresist layer 326 may be formed above the dielectric masking layer 324, and a pattern 328 may be formed in the photoresist layer 326. A deposition tool may be used to form the photoresist layer on the dielectric masking layer 324 (e.g., using a spin-coating technique or another suitable deposition technique). In some implementations, a bottom antireflective coating (BARC) is first deposited on the dielectric masking layer 324, and then the photoresist layer 326 is deposited onto the BARC. An exposure tool may be used to expose the photoresist layer 326 to a radiation source to pattern the photoresist layer 326. A developer tool may be used to develop and remove portions of the photoresist layer 326 to expose the pattern 328.

As shown in FIG. 3L, an etch tool may be used to etch the dielectric masking layer 324 based on the pattern 328 in the photoresist layer 326, to transfer the pattern 328 to the dielectric masking layer 324. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 324 compared to the material of the underlying ILD layer 136. Thus, the etch operation may stop on the ILD layer 136, with minimal etching to the ILD layer 136.

One or more additional etch operations may be performed to etch through the ILD layer 136, through the ESL 134, and through the ILD layer 132 to form recesses 330, where bottom surfaces of the recesses 330 expose portions of top surfaces of the underlying top metal layers 140. The etch operations may include, for example, a gas-based etch operation in which a different type of etchant is used, as compared to the etchant that was used to transfer the pattern 328 to the dielectric masking layer 324. Thus, the semiconductor device 102 may be transferred from a first etch tool (in which the pattern 328 was transferred to the dielectric masking layer 324) to a second etch tool (in which the ILD layer 136, the ESL 130, and the ILD layer 132 are etched) using a wafer/die transport tool to reduce the likelihood of cross-contamination between the first and second etch tools. Alternatively, an etch tool that has multiple processing chambers (e.g., a cluster tool) may be used, and the semiconductor device 102 may be transferred between processing chambers of the etch tool for etching using different types of etchants.

In some implementations, a dual damascene process is used to form the recesses 330. For example, and as shown in FIG. 3L, an interconnect structure (e.g., via) portion of the recesses 330 may be formed in and/or through the ILD layer 132 and ESL 130. A trench portion of the recesses 330 may be formed in the ILD layer 136 and in the ESL 134 above the interconnect structure portion.

An interconnect structure-first dual damascene procedure can be performed in which the recesses 330 are formed by forming the interconnect structure portion before forming the trench portion. In some implementations, a trench-first dual damascene procedure can be performed in which the recesses 330 are formed by forming the trench portion before forming the interconnect structure portion.

As shown in FIG. 3M, one or more deposition tools may be used to deposit conductive material 332 in the recesses 330 to form the top metal layers 144, and the top vias 142, using a PVD technique, an ALD technique, a CVD technique, an electroplating technique (e.g., an electro-chemical plating technique), and/or another suitable deposition technique. As noted herein, the conductive material to form the top metal layers 144 and the top vias 142 may include, for example, tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the top metal layers 144 and the top vias 142. The one or more liner layers may include barrier liners, adhesion liners, and/or another type of liners. Examples of materials for the one or more liners include tantalum nitride (TaN) and/or titanium nitride (TiN), among other examples.

Referring to FIG. 3N, a planarization tool may be used to planarize the surface of the ILD layer 136 to remove the dielectric masking layer 324, and excess portions of the conductive material 332 formed on the dielectric masking layer 324 and over the top surfaces of the ILD layer 136. The planarization also removes the stepped profile from the top surface of the ILD layer 136.

The top surfaces of the testing vias 160 may contact a bottom surface of a first portion of the ESL 134 corresponding to a raised portion 322 of the ILD layer 132. A top metal layer 144 may be formed through a top portion of the ILD layer 132 having the greater thickness T2 in the z-direction. The top metal layer 144 extends below a second portion of the ESL 134 that corresponds to another raised portion 322 of the ILD layer 132. The top metal layer 144 lands on and contacts two top vias 142. The height H1 of the top vias 142 in the z-direction is less than a height H2 of the testing vias 160 in the z-direction.

As shown in FIG. 3O, the ESLs 146 and 150 of the bonding layer 108, the dielectric layers 148 and 152 of the bonding layer 108, and the bonding dielectric layer 158 of the bonding layer 108 may be formed above the interconnect layer 106. Bonding vias 154 may be formed in and/or through the ESL 146 and the dielectric layer 148, and may be formed on top metal layers 144. Bonding pads 156 may be formed in and/or through the ESL 150, the dielectric layer 152, and/or the bonding dielectric layer 158, and may be formed on the bonding vias 154.

One or more deposition tools may be used to deposit the ESL 146, the dielectric layer 148, the ESL 150, the dielectric layer 152, and/or the bonding dielectric layer 158 using a PVD technique, an ALD technique, a CVD technique, an oxidation technique, and/or another suitable deposition technique. In some implementations, a planarization tool may be used to perform a planarization operation (e.g., a CMP operation) to planarize the ESL 146, the dielectric layer 148, the ESL 150, the dielectric layer 152, and/or the bonding dielectric layer 158.

In some implementations, the bonding vias 154 and the bonding pads 156 may be formed in dual damascene recesses. For example, a first etch operation may be performed to form a trench portion of the dual damascene recesses, and a second etch operation may be performed to form a via portion of the dual damascene recesses. As another example, a first etch operation may be performed to form a via portion of the dual damascene recesses, and a second etch operation may be performed to form a trench portion of the dual damascene recesses. The bonding vias 154 may be formed in the via portions of the dual damascene recesses, and the bonding pads 156 may be formed in the trench portions of the dual damascene recesses.

A deposition tool may be used to deposit the bonding vias 154 and bonding pads 156 using a CVD technique, a PVD technique, an ALD technique, an electroplating technique, and/or another suitable deposition technique. The bonding vias 154 and bonding pads 156 may be deposited in one or more deposition operations. In some implementations, a seed layer is first deposited in the dual damascene recesses, and the bonding vias 154 and bonding pads 156 are deposited on the seed layer. In some implementations, a liner layer (e.g., an adhesion liner, a barrier liner) is first deposited in the dual damascene recesses, and the bonding vias 154 and bonding pads 156 are deposited on the liner layer. The liner layer may include a suitable liner material such as a tantalum nitride (TaN) and/or titanium nitride (TiN), among other examples. In some implementations, a planarization tool is used to perform a planarization operation (e.g., a CMP operation) to planarize the bonding pads 156 after the bonding vias 154 and bonding pads 156 are deposited.

As indicated above, FIGS. 3A-3O are provided as an example. Other examples may differ from what is described with regard to FIGS. 3A-3O.

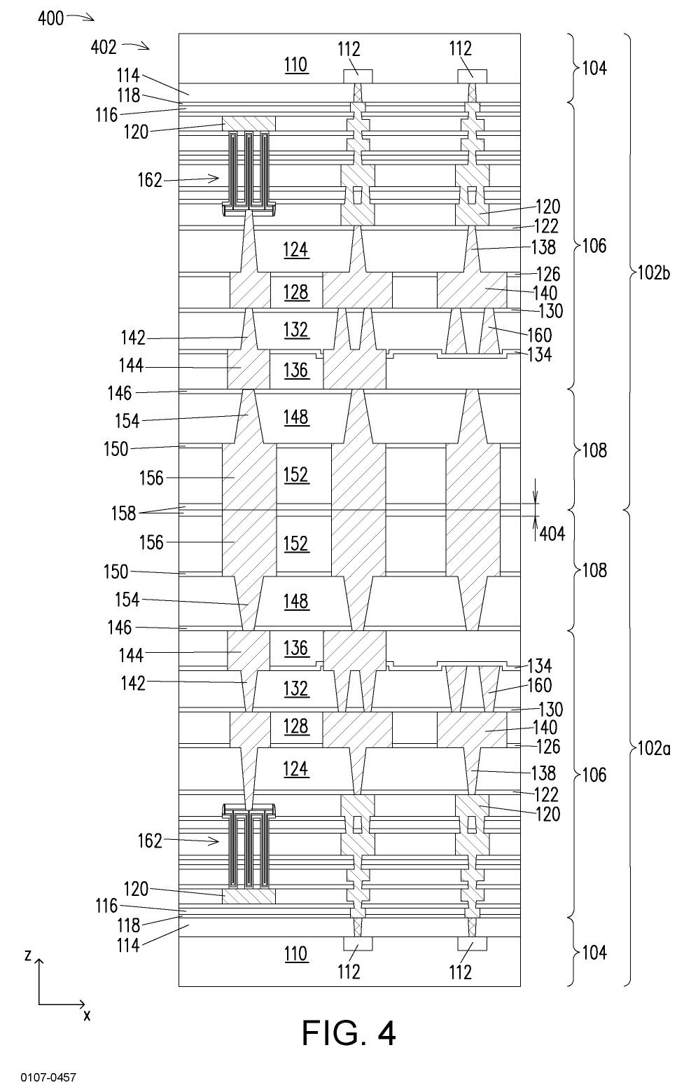

FIG. 4 is a diagram of an example implementation 400 of a semiconductor package 402. As shown in a cross-section view of the semiconductor package 402 in FIG. 4, the semiconductor package 402 is a three-dimensional (3D) structure that includes a semiconductor device 102a (e.g., a first semiconductor die) and a semiconductor device 102b (e.g., a second semiconductor die) that are directly bonded together at a bonding interface 404 such that the semiconductor device 102a and the semiconductor device 102b are stacked and vertically arranged in the semiconductor package 402. The semiconductor device 102a and the semiconductor device 102b may each include a similar combination and arrangement of layers and/or structures as the example implementation 100 of the semiconductor device 102 illustrated in FIG. 1, and may be formed by similar semiconductor processing operations and/or techniques as described in connection with FIGS. 3A-3O.

At the bonding interface 404, the semiconductor device 102a and the semiconductor device 102b may be bonded together with a combination of metal-to-metal bonds and dielectric-to-dielectric bonds. For example, the bonding pads 156 of the semiconductor device 102a may be bonded to the bonding pads 156 of the semiconductor device 120b in metal-to-metal bonds at the bonding interface 404. As another example, the bonding dielectric layer 158 of the semiconductor device 102a may be bonded to the bonding dielectric layer 158 of the semiconductor device 102b in a dielectric-to-dielectric bond at the bonding interface 404.

In some implementations, a misalignment (not shown) may occur at the bonding interface 404 between a bonding pad 156 of the semiconductor device 102a and a bonding pad 156 of the semiconductor device 102b. Thus, misalignment regions may occur on one or more sides of the bond between the bonding pads 156 of the semiconductor devices 102a and 102b. A misalignment region may include a portion of the bonding surface of the bonding pad 156 of the semiconductor device 102a that is in contact with the bonding dielectric layer 158 of the semiconductor device 102b. Another misalignment region may include a portion of the bonding surface of the bonding pad 156 of the semiconductor device 102b that is in contact with the bonding dielectric layer 158 of the semiconductor device 102a. In other words, the bonding pads 156 are laterally offset such that the edges of the bonding pads 156 of the semiconductor devices 102a and 102b that are bonded together may be misaligned.

In some implementations, the semiconductor device 102a may include a capacitor structure 162 that is directly connected to a bonding via 154 in the bonding layer 108 of the semiconductor device 102a. The capacitor structure 162 may be electrically connected to a bonding pad 156 of the semiconductor device 102b through the bonding via 154 and through a bonding pad 156 of the semiconductor device 102a that is physically connected with the bonding via 154 and the bonding pad 156 of the semiconductor device 102b.

Additionally and/or alternatively, the semiconductor device 102b may include a capacitor structure 162 that is directly connected to a bonding via 154 in the bonding layer 108 of the semiconductor device 102b. The capacitor structure 162 may be electrically connected to a bonding pad 156 of the semiconductor device 102a through the bonding via 154 and through a bonding pad 156 of the semiconductor device 102b that is physically connected with the bonding via 154 and the bonding pad 156 of the semiconductor device 102a.

As indicated above, FIG. 4 is provided as an example. Other examples may differ from what is described with regard to FIG. 4.

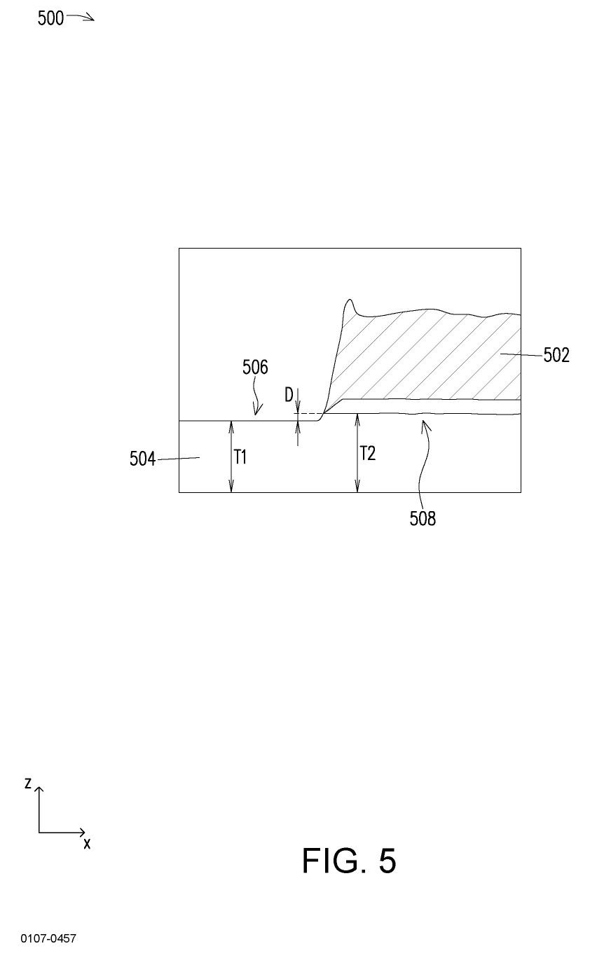

FIG. 5 is a diagram of an example implementation 500 of a semiconductor device described herein. As shown in FIG. 5, an aluminum sacrificial test pad 502 is disposed on an ILD layer 504. The ILD layer 504 includes a recessed portion 506 and a raised portion on which the aluminum sacrificial test pad sits. An etch operation removes portions of a metal layer, which then exposes underlying portions of the ILD layer 504. The etch operation further removes an exposed portion of the ILD layer 504 adjacent to the sacrificial test pad 502 to form the recessed portion 506 in the ILD layer 504. The sacrificial test pad 502 is on a raised portion 508 of the ILD layer 504 adjacent to the recessed portion 506. In some implementations, the etch operation includes a wet etch operation. For example, an etch tool may be used to etch exposed portions of the metal layer in a wet etch operation, where tetramethyl ammonium hydroxide (TMAH) is used as the etchant to remove portions of the metal layer to form the sacrificial test pad 502.

As a result of the etching, the remaining portion of the ILD layer 504 has a stepped (e.g., non-planar) profile with different portions having different heights in the z-direction based on a thickness T1 of the ILD layer 504 corresponding to the recessed portion 506, and a thickness T2 of the ILD layer 504 corresponding to the raised portion 508, where the thickness T2 is greater than the thickness T1. In some implementations, a depth D of the recessed portion 506 may be greater than approximately 5 nanometers. However, other values for the depth of the recessed portion 506 are within the scope of the present disclosure.

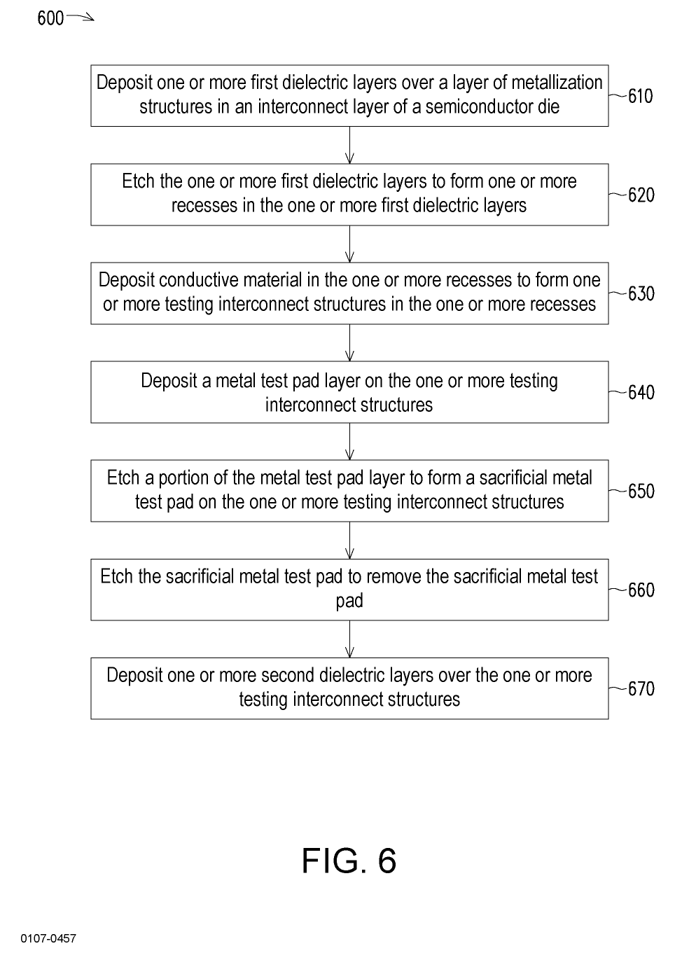

FIG. 6 is a flowchart of an example process 600 associated with forming a semiconductor device. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include depositing one or more first dielectric layers over a layer of metallization structures in an interconnect layer of a semiconductor die (block 610). For example, one or more semiconductor processing tools may be used to deposit one or more first dielectric layers (e.g., ESL 130, ILD layer 132) over a layer of metallization structures (e.g., top metal layers 140) in an interconnect layer (e.g., interconnect layer 106) of a semiconductor die (e.g., semiconductor device 102), as described herein.

As further shown in FIG. 6, process 600 may include etching the one or more first dielectric layers to form one or more recesses in the one or more first dielectric layers (block 620). For example, one or more semiconductor processing tools may be used to etch the one or more first dielectric layers to form one or more recesses (e.g., recesses 308) in the one or more first dielectric layers, as described herein.

As further shown in FIG. 6, process 600 may include depositing conductive material in the one or more recesses to form one or more testing interconnect structures in the one or more recesses (block 630). For example, one or more semiconductor processing tools may be used to deposit conductive material in the one or more recesses to form one or more testing interconnect structures (e.g., testing vias 160) in the one or more recesses, as described herein. In some implementations, the one or more testing interconnect structures are formed on a metallization structure of the metallization structures.

As further shown in FIG. 6, process 600 may include depositing a metal test pad layer on the one or more testing interconnect structures (block 640). For example, one or more semiconductor processing tools may be used to deposit a metal test pad layer (e.g., metal layer 310) on the one or more testing interconnect structures, as described herein.

As further shown in FIG. 6, process 600 may include etching a portion of the metal test pad layer to form a sacrificial metal test pad on the one or more testing interconnect structures (block 650). For example, one or more semiconductor processing tools may be used to etch a portion of the metal test pad layer to form a sacrificial metal test pad (e.g., sacrificial test pad 318) on the one or more testing interconnect structures, as described herein.

As further shown in FIG. 6, process 600 may include etching the sacrificial metal test pad to remove the sacrificial metal test pad (block 660). For example, one or more semiconductor processing tools may be used to etch the sacrificial metal test pad to remove the sacrificial metal test pad, as described herein.

As further shown in FIG. 6, process 600 may include depositing one or more second dielectric layers over the one or more testing interconnect structures (block 670). For example, one or more semiconductor processing tools may be used to deposit one or more second dielectric layers (e.g., ESL 134, ILD layer 136) over the one or more testing interconnect structures, as described herein.

Process 600 may include additional implementations, such as any single implementation or any combination of implementations described below and/or in connection with one or more other processes described elsewhere herein.

In a first implementation, etching the portion of the metal test pad layer results in removal of the portion of the metal test pad layer, which exposes a portion of a first dielectric layer (e.g., ILD layer 132) of the one or more first dielectric layers, and the portion of the first dielectric layer is etched to form a plurality of recessed portions (e.g., recessed portions 320) in the first dielectric layer adjacent to the sacrificial metal test pad.

In a second implementation, alone or in combination with the first implementation, the sacrificial metal test pad is on a raised portion (e.g., raised portion 322) of the first dielectric layer, where the raised portion is adjacent to the plurality of recessed portions, and where a second dielectric layer (e.g., ESL 134) of the one or more second dielectric layers is conformally deposited on the plurality of recessed portions, and on the raised portion.

In a third implementation, alone or in combination with one or more of the first and second implementations, the one or more testing interconnect structures are under the raised portion of the first dielectric layer.

In a fourth implementation, alone or in combination with one or more of the first through third implementations, a portion of the one or more second dielectric layers is further deposited on a portion of the one or more first dielectric layers laterally adjacent to the one or more testing interconnect structures in a first direction (e.g., x-direction).

In a fifth implementation, alone or in combination with one or more of the first through fourth implementations, process 600 includes etching the portion of the one or more second dielectric layers and the portion of the one or more first dielectric layers to form one or more additional recesses (e.g., 330) in the portion of the one or more second dielectric layers and in the portion of the one or more first dielectric layers, and depositing additional conductive material (e.g., conductive material 332) in the one or more additional recesses to form one or more interconnect structures (e.g., top vias 142) in the one or more additional recesses, where the one or more interconnect structures are laterally adjacent to the one or more testing interconnect structures in the first direction.

In a sixth implementation, alone or in combination with one or more of the first through fifth implementations, a height of the one or more testing interconnect structures in a second direction (e.g., z-direction) substantially perpendicular to the first direction is greater than a height of the one or more interconnect structures in the second direction.

In a seventh implementation, alone or in combination with one or more of the first through sixth implementations, process 600 includes performing one or more testing operations using the sacrificial metal test pad, where the one or more testing operations include at least one of circuit probe (CP) testing or electrical voltage stress (EVS) testing.

In an eighth implementation, alone or in combination with one or more of the first through seventh implementations, process 600 includes depositing one or more bonding dielectric layers (e.g., ESL 146, dielectric layer 148, ESL 150, dielectric layer 152, bonding dielectric layer 158) over the one or more second dielectric layers, and depositing a plurality of bonding structures (e.g., bonding vias 154, e.g., bonding pads 156) in the one or more bonding dielectric layers.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

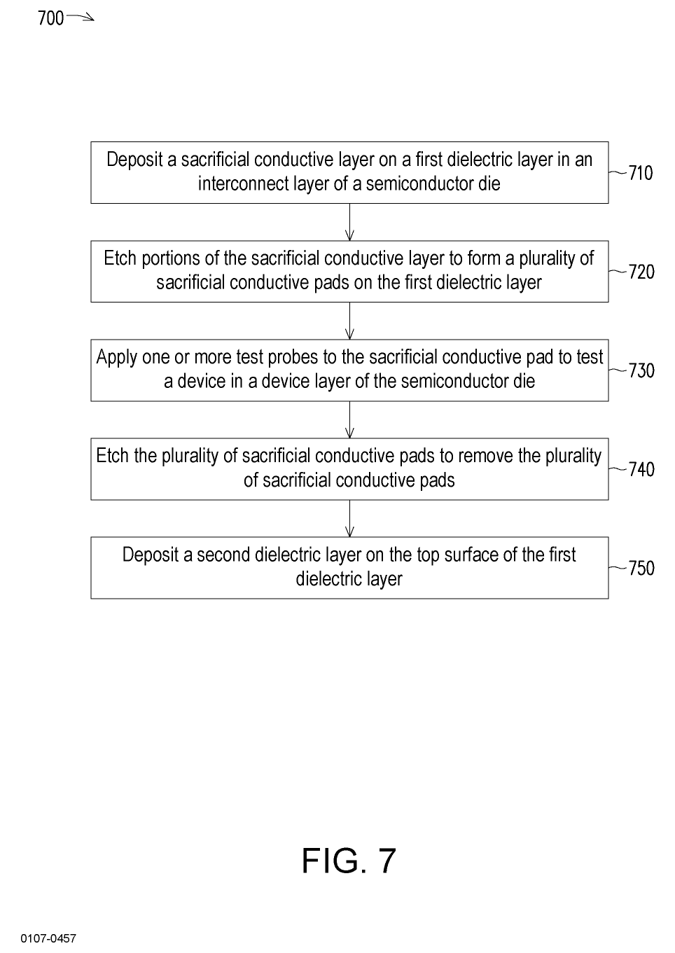

FIG. 7 is a flowchart of an example process 700 associated with forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include depositing a sacrificial conductive layer on a first dielectric layer in an interconnect layer of a semiconductor die (block 710). For example, one or more semiconductor processing tools may be used to deposit a sacrificial conductive layer (e.g., metal layer 310) on a first dielectric layer (e.g., ILD layer 132) in an interconnect layer (e.g., interconnect layer 106) of a semiconductor die (e.g., semiconductor device 102), as described herein.

As further shown in FIG. 7, process 700 may include etching portions of the sacrificial conductive layer to form a plurality of sacrificial conductive pads on the first dielectric layer (block 720). For example, one or more semiconductor processing tools may be used to etch portions of the sacrificial conductive layer to form a plurality of sacrificial conductive pads (e.g., sacrificial test pads 318)) on the first dielectric layer, as described herein. In some implementations, etching portions of the sacrificial conductive layer results in formation of a stepped profile in a top surface of the first dielectric layer. In some implementations, a sacrificial conductive pad of the plurality of sacrificial conductive pads is formed on a testing interconnect structure (e.g., testing via 160). In some implementations, the testing interconnect structure is disposed through the first dielectric layer.

As further shown in FIG. 7, process 700 may include applying one or more test probes to the sacrificial conductive pad to test a device in a device layer of the semiconductor die (block 730). For example, one or more semiconductor processing tools may be used to apply one or more test probes to the sacrificial conductive pad to test a device (e.g., integrated circuit device 112) in a device layer (e.g., device layer 104) of the semiconductor die, as described herein. In some implementations, the device is electrically connected to the one or more test probes through the sacrificial conductive pad and the testing interconnect structure.

As further shown in FIG. 7, process 700 may include etching the plurality of sacrificial conductive pads to remove the plurality of sacrificial conductive pads (block 740). For example, one or more semiconductor processing tools may be used to etch the plurality of sacrificial conductive pads to remove the plurality of sacrificial conductive pads, as described herein.

As further shown in FIG. 7, process 700 may include depositing a second dielectric layer on the top surface of the first dielectric layer (block 750). For example, one or more semiconductor processing tools may be used to deposit a second dielectric layer (e.g., ESL 134, ILD layer 136) on the top surface of the first dielectric layer, as described herein. In some implementations, the second dielectric layer conforms to the stepped profile.

Process 700 may include additional implementations, such as any single implementation or any combination of implementations described below and/or in connection with one or more other processes described elsewhere herein.

In a first implementation, etching the plurality of sacrificial conductive pads exposes a top surface of the testing interconnect structure, and the second dielectric layer contacts the top surface of the testing interconnect structure.

In a second implementation, alone or in combination with the first implementation, the stepped profile includes a plurality of recessed portions (e.g., recess portions 320) and a plurality of raised portions (e.g., raised portions 322), and the testing interconnect structure is formed under a raised portion of the plurality of raised portions.

In a third implementation, alone or in combination with one or more of the first and second implementations, process 700 includes depositing an interconnect structure (e.g., top via 142) in the first dielectric layer laterally adjacent to the testing interconnect structure, and depositing a metallization structure (e.g., top metal layer 144) through the second dielectric layer, where the metallization structure is disposed over and contacts the interconnect structure.

In a fourth implementation, alone or in combination with one or more of the first through third implementations, a height of a topmost portion of the interconnect structure adjacent the metallization structure is less than a height of a topmost portion of the testing interconnect structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, sacrificial test pads are formed in a semiconductor die, used for testing operations, and then removed after the testing operations have been completed. The removal of the sacrificial test pads eliminates any adverse effects (e.g., on structures and/or bonding of the semiconductor die) that may have been caused by damage to the sacrificial test pads from multiple test probe applications. For example, the removal of the sacrificial test pads prior to forming portions of an interconnect layer and forming a bonding region of the semiconductor die prevents any uneven surfaces, increased oxidation, and/or etching contamination that could have been caused by marks, recesses, protrusions, and/or other imperfections in the sacrificial test pads. As a result, metallization structures, interconnect structures, and bonding structures may be subsequently formed without defects that may have been attributed to damaged test pads. Testing interconnect structures used in connection with the testing operations may remain in the semiconductor die, with one or more dielectric layers formed over the testing interconnect structures. In this way, increased performance and bonding stability may be achieved for the semiconductor die in comparison to devices in which test pads remain in a final structure.

As described in greater detail above, some implementations described herein provide a method. The method includes depositing one or more first dielectric layers over a layer of metallization structures in an interconnect layer of a semiconductor die. The method includes etching the one or more first dielectric layers to form one or more recesses in the one or more first dielectric layers. The method includes depositing conductive material in the one or more recesses to form one or more testing interconnect structures in the one or more recesses, where the one or more testing interconnect structures are formed on a metallization structure of the metallization structures. The method includes depositing a metal test pad layer on the one or more testing interconnect structures. The method includes etching a portion of the metal test pad layer to form a sacrificial metal test pad on the one or more testing interconnect structures. The method includes etching the sacrificial metal test pad to remove the sacrificial metal test pad. The method includes depositing one or more second dielectric layers over the one or more testing interconnect structures.

As described in greater detail above, some implementations described herein provide a method. The method includes depositing a sacrificial conductive layer on a first dielectric layer in an interconnect layer of a semiconductor die. The method includes etching portions of the sacrificial conductive layer to form a plurality of sacrificial conductive pads on the first dielectric layer, where etching portions of the sacrificial conductive layer results in formation of a stepped profile in a top surface of the first dielectric layer, where a sacrificial conductive pad of the plurality of sacrificial conductive pads is formed on a testing interconnect structure, and where the testing interconnect structure is disposed through the first dielectric layer. The method includes applying one or more test probes to the sacrificial conductive pad to test a device in a device layer of the semiconductor die, where the device is electrically connected to the one or more test probes through the sacrificial conductive pad and the testing interconnect structure. The method includes etching the plurality of sacrificial conductive pads to remove the plurality of sacrificial conductive pads. The method includes depositing a second dielectric layer on the top surface of the first dielectric layer, where the second dielectric layer conforms to the stepped profile.

As described in greater detail above, some implementations described herein provide a semiconductor device. The semiconductor device includes a plurality of dielectric layers that are arranged in a first direction above a substrate layer, where the first direction is approximately perpendicular to a top surface of the substrate layer. The semiconductor device includes a plurality of metallization structures disposed in one or more first dielectric layers of the plurality of dielectric layers, where the plurality of metallization structures are arranged in a second direction approximately perpendicular to the first direction. The semiconductor device includes one or more testing interconnect structures disposed through one or more second dielectric layers, where the one or more testing interconnect structures are disposed on a first metallization structure of the plurality of metallization structures, where a third dielectric layer of the plurality of dielectric layers is over a top surface of the one or more testing interconnect structures, and where the third dielectric layer includes a profile having alternating heights in the first direction. The semiconductor device includes one or more interconnect structures disposed through the one or more second dielectric layers, where the one or more interconnect structures are disposed on a second metallization structure of the plurality of metallization structures.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing one or more first dielectric layers over a layer of metallization structures in an interconnect layer of a semiconductor die;
etching the one or more first dielectric layers to form one or more recesses in the one or more first dielectric layers;
depositing conductive material in the one or more recesses to form one or more testing interconnect structures in the one or more recesses,
wherein the one or more testing interconnect structures are formed on a metallization structure of the metallization structures;
depositing a metal test pad layer on the one or more testing interconnect structures;
etching a portion of the metal test pad layer to form a sacrificial metal test pad on the one or more testing interconnect structures;
etching the sacrificial metal test pad to remove the sacrificial metal test pad; and
depositing one or more second dielectric layers over the one or more testing interconnect structures.

2. The method of claim 1, wherein etching the portion of the metal test pad layer results in removal of the portion of the metal test pad layer, which exposes a portion of a first dielectric layer of the one or more first dielectric layers, and
wherein the portion of the first dielectric layer is etched to form a plurality of recessed portions in the first dielectric layer adjacent to the sacrificial metal test pad.

3. The method of claim 2, wherein the sacrificial metal test pad is on a raised portion of the first dielectric layer,
wherein the raised portion is adjacent to the plurality of recessed portions, and
wherein a second dielectric layer of the one or more second dielectric layers is conformally deposited on the plurality of recessed portions, and on the raised portion.

4. The method of claim 3, wherein the one or more testing interconnect structures are under the raised portion of the first dielectric layer.

5. The method of claim 1, wherein a portion of the one or more second dielectric layers is further deposited on a portion of the one or more first dielectric layers laterally adjacent to the
the one or more testing interconnect structures in a first direction.

6. The method of claim 5, further comprising:
etching the portion of the one or more second dielectric layers and the portion of the one or more first dielectric layers to form one or more additional recesses in the portion of the one or more second dielectric layers and in the portion of the one or more first dielectric layers; and
depositing additional conductive material in the one or more additional recesses to form one or more interconnect structures in the one or more additional recesses,
wherein the one or more interconnect structures are laterally adjacent to the one or more testing interconnect structures in the first direction.

7. The method of claim 6, wherein a height of the one or more testing interconnect structures in a second direction substantially perpendicular to the first direction is greater than a height of the one or more interconnect structures in the second direction.

8. The method of claim 1, further comprising performing one or more testing operations using the sacrificial metal test pad,
wherein the one or more testing operations comprise at least one of circuit probe (CP) testing or electrical voltage stress (EVS) testing.

9. The method of claim 1, further comprising:
depositing one or more bonding dielectric layers over the one or more second dielectric layers; and
depositing a plurality of bonding structures in the one or more bonding dielectric layers.

10. A method, comprising:
depositing a sacrificial conductive layer on a first dielectric layer in an interconnect layer of a semiconductor die;
etching portions of the sacrificial conductive layer to form a plurality of sacrificial conductive pads on the first dielectric layer,
wherein etching portions of the sacrificial conductive layer results in formation of a stepped profile in a top surface of the first dielectric layer,
wherein a sacrificial conductive pad of the plurality of sacrificial conductive pads is formed on a testing interconnect structure, and
wherein the testing interconnect structure is disposed through the first dielectric layer;
applying one or more test probes to the sacrificial conductive pad to test a device in a device layer of the semiconductor die,
wherein the device is electrically connected to the one or more test probes through the sacrificial conductive pad and the testing interconnect structure;
etching the plurality of sacrificial conductive pads to remove the plurality of sacrificial conductive pads; and
depositing a second dielectric layer on the top surface of the first dielectric layer,
wherein the second dielectric layer conforms to the stepped profile.

11. The method of claim 10, wherein etching the plurality of sacrificial conductive pads exposes a top surface of the testing interconnect structure, and
wherein the second dielectric layer contacts the top surface of the testing interconnect structure.

12. The method of claim 10, wherein the stepped profile comprises a plurality of recessed portions and a plurality of raised portions, and
wherein the testing interconnect structure is formed under a raised portion of the plurality of raised portions.

13. The method of claim 10, further comprising:
depositing an interconnect structure in the first dielectric layer laterally adjacent to the testing interconnect structure; and
depositing a metallization structure through the second dielectric layer,
wherein the metallization structure is disposed over and contacts the interconnect structure.

14. The method of claim 13, wherein a height of a topmost portion of the interconnect structure adjacent the metallization structure is less than a height of a topmost portion of the testing interconnect structure.

15. A semiconductor device, comprising:
a plurality of dielectric layers that are arranged in a first direction above a substrate layer,
wherein the first direction is approximately perpendicular to a top surface of the substrate layer;
a plurality of metallization structures disposed in one or more first dielectric layers of the plurality of dielectric layers,
wherein the plurality of metallization structures are arranged in a second direction approximately perpendicular to the first direction;
one or more testing interconnect structures disposed through one or more second dielectric layers,
wherein the one or more testing interconnect structures are disposed on a first metallization structure of the plurality of metallization structures,
wherein a third dielectric layer of the plurality of dielectric layers is over a top surface of the one or more testing interconnect structures, and
wherein the third dielectric layer comprises a profile having alternating heights in the first direction; and
one or more interconnect structures disposed through the one or more second dielectric layers,
wherein the one or more interconnect structures are disposed on a second metallization structure of the plurality of metallization structures.

16. The semiconductor device of claim 15, wherein a height of the one or more interconnect structures in the first direction is less than a height of the one or more testing interconnect structures in the first direction.

17. The semiconductor device of claim 15, wherein the profile of the third dielectric layer comprises a plurality of recessed portions, and
wherein the one or more testing interconnect structures and the one or more interconnect structures are laterally adjacent to a recessed portion of the plurality of recessed portions.

18. The semiconductor device of claim 15, wherein the profile of the third dielectric layer comprises a plurality of raised portions, and
wherein the top surface of the one or more testing interconnect structures contacts a bottom surface of a first raised portion of the plurality of raised portions.

19. The semiconductor device of claim 18, further comprising a top metallization structure disposed on the one or more interconnect structures,
wherein the top metallization structure is disposed through a second raised portion of the plurality of raised portions into a dielectric layer of the one or more second dielectric layers.

20. The semiconductor device of claim 15, wherein a fourth dielectric layer of the plurality of dielectric layers covers a top surface of the third dielectric layer.
